(19) United States
(12) Patent Application Publication
(10) Pub. No.: US 2025/0239542 A1
(43) Pub. Date: Jul. 24, 2025

(54) SEMICONDUCTOR PACKAGE COMPRISING AN END-FIRE ANTENNA ARRAY

(71) Applicant: Intel Corporation, Santa Clara, CA (US)

(72) Inventors: Tae Young YANG, Portland, OR (US); Kexin HU, Atlanta, GA (US); Ofir DEGANI, Nes-Ammin (IL); Oren Ezra AVRAHAM, Givat Shmuel (IL); Bryce HORINE, Portland, OR (US); Harry G. SKINNER, Beaverton, OR (US)

(21) Appl. No.: 18/972,524

(22) Filed: Dec. 6, 2024

(30) Foreign Application Priority Data
Dec. 20, 2023 (WO) PCT/US2023/084980

(51) Int. Cl. H01L 23/66; H01L 23/538

(52) U.S. Cl. CPC H01L 23/66; H01L 23/5384; H01L 23/5386; H01L 2223/6616; H01L 2223/6627; H01L 2223/6677

(57) ABSTRACT

Provided is a semiconductor package comprising a layer stack. The layer stack of the semiconductor package comprises a first plurality of conductive layers forming a plurality of antenna elements of an end-fire antenna array, wherein each antenna element is configured for a first polarization and for a second polarization, and at least one conductive signal routing layer adjacent to the first plurality of conductive layers, the conductive signal routing layer comprising first routing traces for the first polarization and second routing traces for the second polarization.

### CROSS-REFERENCE TO RELATED APPLICATION

This application claims priority under 35 U.S.C. §§ 120 and 365 (c) to International Application No. PCT/US2023/084980, filed on Dec. 20, 2023, the entirety of which is incorporated herein by reference.

### FIELD

The present disclosure generally relates to antennas implemented in semiconductor packages, and, more particularly, to end-fire antenna arrays implemented in semiconductor packages.

### BACKGROUND

As the world is becoming digital, computing devices need pervasive connectivity to collect, store, move and analyze large data. This has posed new performance challenges for future Wireless Fidelity (Wi-Fi) and client/edge platforms, including ultra-low latency, high resilience, large data volumes, and low power consumption. Recently, IEEE Standards and Wi-Fi Alliance approved creation of “Integrated Millimeter-Wave (IMW)” working group to intercept Wi-Fi 8 R2+ (2029) standard. The millimeter-wave (mmW) Wi-Fi exploits up to 14 GHz (57-71 GHz) of additional bandwidth, co-runs with sub-8 GHz Wi-Fi, and introduces new use cases including Augmented Reality (AR)/Virtual Reality (VR) at super low latency (<5 ms), docking/extended display, and gesture recognition.

It is well known that beamforming in mmW Wi-Fi devices is a highly sought-after feature to minimize and mitigate higher path loss. Conventional beamforming arrays in Antenna-in-Package (AiP) can be achieved by a broadside antenna array configuration. Antenna in Package (AiP) or antenna in module (AiM) technology is an antenna packaging solution that implements an antenna or antennas in an integrated circuit (IC) package that may comprise one or more radio frequency (RF) chips (transceiver).

A broadside antenna array is an array of antenna elements which are placed parallel to each other along an axis of the antenna array. The antenna elements are fed in phase and the direction of maximum radiation is perpendicular to the axis and/or a plane spanned by the antenna elements. These designs may utilize simple antenna structures that have been proven to get easily fabricated, e.g., patch antenna arrays, offering good front-to-back (F/B) ratio of radiation pattern, acceptable beam scanning range, and straightforward dual-polarization implementation. However, broadside arrays often suffer from limited angular coverage and high profile. For instance, as shown in FIG. 1A, when integrated into a mobile computing device, for example a laptop, broadside arrays may need to be placed vertically, and a keep-out zone is required between the antenna array and the edge of the laptop, to avoid radiation pattern distortion. This could lead to limitations on the minimum thickness of the laptop that broadside-beam-based AiP can be integrated into. In addition, it is challenging to tilt beams of both polarizations toward a Wi-Fi access point (AP). Without the beam tilt, the main beam is not directed to the AP and/or a significant portion of the beam can hit the surface that laptop is sitting on. These result in reducing data throughputs.

On the other hand, end-fire arrays (as shown in FIG. 1B) may provide a wider angular coverage in a low-profile structure, which can effectively and efficiently reduce AiP height by 50% or more (compared to broadside antenna arrays) to support ultra-thin laptops. An end fire antenna array structure is similar to a broadside antenna array from the point of view of arrangement. However, the main difference is in the direction of maximum radiation. While for the broadside antenna array the direction of the maximum radiation is perpendicular to the axis of array, the end fire antenna array the direction of the maximum radiation is along the axis of the antenna array. The antenna elements of an end fire antenna array are fed with a phase difference equal to the separation of adjacent antenna elements. However, in a dual-polarized configuration, traditional end-fire arrays come with complex structures. Individual antenna element design, array feeding, and signal routing are necessary for each polarization, resulting in challenges in fabrication and integration. This can also cause low isolation level and high insertion loss when a cost-effective package stack-up is considered.

SIW (Substrate Integrated Waveguide) antenna structure is popular for vertical polarized end-fire antenna elements due to its small physical size (compared to full-size waveguide antenna) and easy integration. However, further lower thickness requirement (e.g., <1.5 mm) of total AiP stack-up will introduce lower Front-to-Back (F/B) ratio (<15 dB) of radiation pattern, causing overall gain reduction. Some end-fire array configurations can support beam tilt in elevation, but these tilted beams are distorted unless large size radome with a keep-out zone is considered.

Previous dual-polarized end-fire antenna arrays in mmW AiP are usually based on SIW (substrate integrated waveguide) structure, combining with slot or magnetic dipoles to support dual polarization, for both the antenna array and the beamforming network. SIW is a low-profile rectangular waveguide formed in a dielectric substrate by densely arraying metallized posts or via holes that connect the upper and lower metal layers of the substrate. The waveguide can be easily fabricated with low-cost mass-production. Fundamental mode of SIW is TE₁₀ for vertical polarization. The main issue in traditional SIW based beamforming end-fire array is the large SIW beamforming network. It is bulky, complicated, and comes with multiple layers or large PCB/Package area. Without a proper design, SIW antenna will also experience low F/B ratio of radiation patten due to the thin substrate.

Typical radome for laptops is designed in a 2D rectangular shape. By placing the radome with enough distance (keep-out zone) from the array, the electromagnetic waves from the antenna can propagate with low loss, less frequency detuning, and minimum radiation patten distortion. On the other hand, the size of the radome with the keep-out zone is larger than actual Antenna-in-Module (AiM) size due to the effectively increased array aperture size. Otherwise, not all radiating electromagnetic waves from antenna can be through the radome, resulting in low radiation efficiency and radiation pattern distortion. Thus, the large size of the radome cannot fit in ultra-thin laptop/edge devices.

Traditional methods to improve F/B ratio for the array is to add reflectors with spacing from the array. The drawback of this approach is increasing package size and surface area, which brings additional complexity and cost.

Conventional topology to achieve wide azimuth angular coverage in client/edge platforms is to use multiple antenna-in-modules (AiMs) surrounding the device. Typically, at least three AiMs are preferred by placing them on the left, right, and front side. The use of multiple antenna-in-module may increase the overall cost.

Previous dual-pol end-fire arrays with beam tilting feature utilized open slots on the top surface of the array. The openings can cause beam distortion and antenna detuning when the radome covers the array. In addition, the previous approach only supports beam tiling in elevation for vertical polarization.

### BRIEF DESCRIPTION OF THE FIGURES

Some examples of apparatuses and/or methods will be described in the following by way of example only, and with reference to the accompanying figures, in which

FIG. 1A shows an exemplary broadside antenna array configuration in AiM for laptop integration;

FIG. 1B shows an end-fire antenna array configuration in AiM for laptop integration;

FIG. 2 illustrates a cutaway side view of a semiconductor package with an end-fire antenna array according to the present disclosure;

FIG. 3 illustrates a cutaway side view of an AiP with six conductive layers according to the present disclosure;

FIG. 4 illustrates a first conductive layer of a substrate layer stack-up;

FIG. 5 illustrates a second conductive layer of a substrate layer stack-up;

FIG. 6 illustrates a third conductive layer of a substrate layer stack-up;

FIG. 7 illustrates a fourth conductive layer of a substrate layer stack-up;

FIG. 8 illustrates a fifth conductive layer of a substrate layer stack-up;

FIG. 9 illustrates a sixth conductive layer of a substrate layer stack-up;

FIG. 10A, B show simulated radiation patterns (H-pol) of the antenna array with symmetric lengths of feed lines to demonstrate correction of beam tilting azimuth plane;

FIG. 11A, B show simulated radiation patterns (H-pol) of the antenna array with different lengths of feedlines to demonstrate beam tilting capability in azimuth plane;

FIG. 12A-D shows a geometry of SIW-slot element antenna-(A) Overall 3-D structure, (B) Top metal layer (L1), (C) Middle metal layer with feeds (L2), and (D) Bottom metal layer (L3);

FIG. 13 shows an overall geometry and dimension of the example dual-polarized end-fire antenna array architecture;

FIG. 14 shows an overall structure of the example dual-polarized 1×4 end-fire antenna array integrated with dual compact BFN;

FIG. 15A, B shows simulated S-parameters of the example dual-polarized end-fire antenna array-(A) Amplitude of active reflection coefficients at beam selection ports and (B) Isolation levels between beam selection ports;

FIG. 16A, B shows simulated radiation patterns of the example dual-polarized end-fire antenna array;

FIG. 17A, B shows simulated S-parameters of the example dual-polarized end-fire antenna array with integrated compact dual BFN—(A) Reflection at beam selection port and (B) Isolation between beam selection port;

FIG. 18 broken into partial views 18-1, 18-2, and 18-3, shows simulated realized gain patterns of the example array at selected frequencies for both polarizations;

FIG. 19 shows a structure of the dual-polarized end-fire antenna array with directors;

FIG. 20 broken into partial views 20-1 and 20-2, shows a simulated radiation pattern of the example dual-polarized end-fire antenna array with directors-(a) H-pol. and (b) V-pol.;

FIG. 21A, B shows a simulated radiation pattern of the example dual-polarized end-fire antenna array with directors showing beam tilting (A) H-pol. (B) V-pol;

FIG. 22 shows a proposed dual-polarized end-fire antenna array architecture with radome and laptop base (cross-sectional view);

FIG. 23 shows a simulation setup for the proposed dual-polarized end-fire antenna array architecture with radome and laptop base;

FIG. 24A, B shows a simulated radiation pattern (V-pol) comparison of antenna array between (A) Case without radome and laptop base (B) Case with radome and laptop base;

FIG. 25A, B shows a simulated radiation pattern (V-pol) comparison of antenna array between (A) Case without radome and laptop base (B) Case with radome and laptop base;

FIG. 26A, B shows a simulated radiation pattern (H-pol) comparison of antenna array between (A) Case without radome and laptop base (B) Case with radome and laptop base;

FIG. 27 shows an illustration of a number of AiMs and angular coverage on laptop base—(a) 3-AiM case and (b) 2-AiM case with proposed beam tilting feature in azimuth plane;

FIG. 28 illustrates a user device in accordance with an aspect; and

FIG. 29A, B illustrate aspects of a radio front end module.

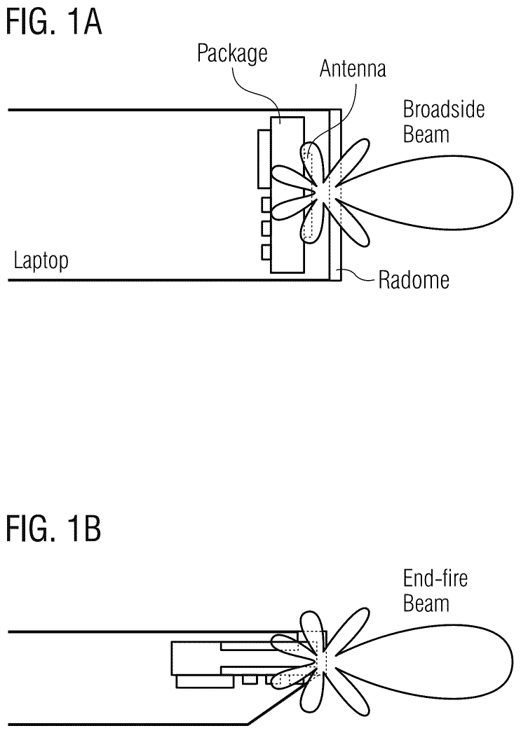

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Antenna-in-package (AiP)/Antenna-in-module (AiM) technology, in which there is an antenna (or antennas) with a transceiver die (or dies) in a standard surface-mounted device, represents an important antenna and packaging technology achievement in recent years. AiP may refer to an antenna structure without transceiver dies. AiM may refer to a package or module where more than an antenna structure is included, such as antenna array, transceiver dies, other SMD components including PMIC, routing package, and antenna package, for example.

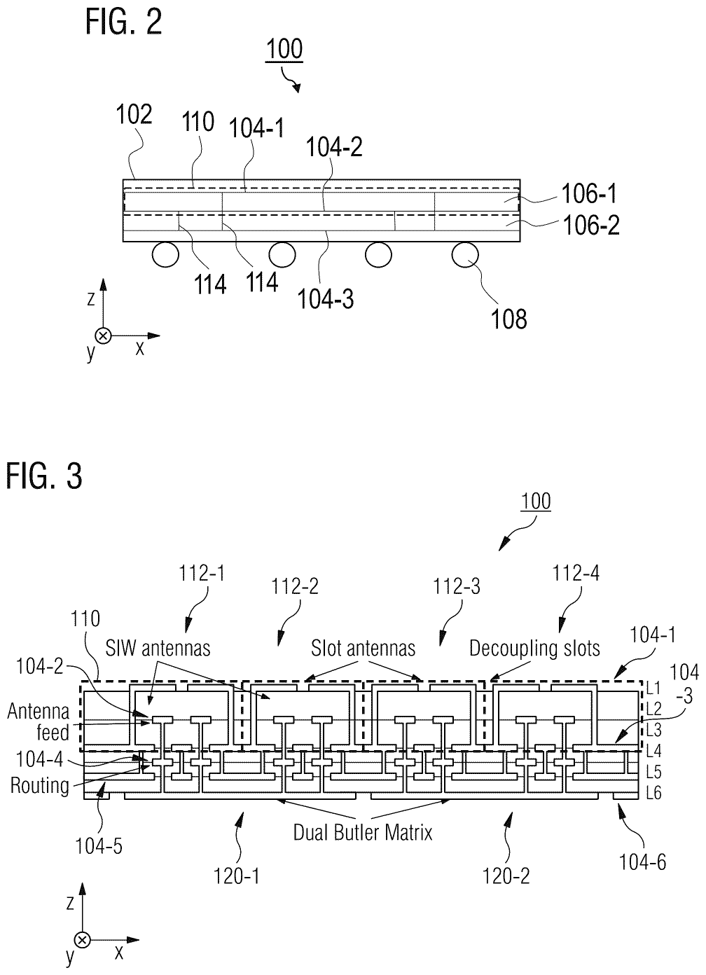

FIG. 2 shows a schematic view of an Antenna-in-Package (AiP) device 100 according to the present disclosure. AiP device 100 may be implemented in a cost-effective multi-layer PCB or other suitable package substrate. AiP device 100 may comprise a semiconductor package housing, an antenna or an antenna array, and optionally also further circuit components of a radiofrequency integrated circuit (RFIC) or portions thereof.

AiP device 100 shown in FIG. 2 may comprise protective housing or mold 102. Mold compounds may be plastics used to encapsulate many types of electronic packages. AiP 100 further comprises, in the housing 102, a stack of a plurality of electrically conductive layers 104-1, 104-2, 104-3. While FIG. 2 shows an example of three conductive layers 104-1, 104-2, 104-3, the skilled person having benefit from the present disclosure will appreciate that also more conductive layers may be employed in actual implementations.

A first plurality of electrically conductive layers 104-1, 104-2 of the layer stack forms a plurality of antenna elements of an integrated end-fire antenna array 110. Conductive layer 104-1 is a top conductive layer of the layer stack and conductive layer 104-2 is a conductive layer underneath the conductive top layer 104-1. Thus, the first plurality of conductive layers 104-1, 104-2 forms an upper part of the layer stack. A material of the conductive layers 104-1, 104-2 may be copper (Cu), for example, or another suitable conductor. Each antenna element of the end-fire antenna array 110 is configured to radiate with a first polarization (e.g., in z-direction) and with at least a second polarization (e.g., in x-direction). That is, the end-fire antenna array 110 may be configured at least as dual polarized end-fire antenna array. Note that radiation direction (power delivery direction) and polarization direction (referenced to E-field orientation/direction) are orthogonal to each other. If a first polarization (i.e. E-field orientation) is aligned with z axis, the radiation direction may be y-axis and magnetic field may be aligned with x-direction at far field region. In some examples, the integrated end-fire antenna array 110 may be configured to operate over a range of frequencies from 57 GHz to 71 GHz. That is, the end-fire antenna array 110 may have a bandwidth of approximately 14 GHz and may thus be useful for millimeter-wave (mmW) Wi-Fi applications. Thus, AiP device 100 may be configured to provide wireless signal transmission and/or reception in the mmW range. AiP device 100 may be part of a mobile user device (such as a smartphone, a tablet, a laptop, etc.) and provide a wireless communication interface for mmW Wi-Fi applications. Millimeter-wave may refer to the band of radio frequencies in the electromagnetic spectrum from 30 to 300 gigahertz (GHz). Radio waves in this band have wavelengths from ten to one millimeter, so it is also called the mm band and radiation in this band is called mm waves.

Thus, end-fire antenna array 110 can be formed in two layers. However, a three-layer structure may be used for enabling dual-polarization. For example, layers L1-L3 in FIG. 3 form dual-pol. end-fire array and L3-L6 form routing & BFN layers.

AiP device 100 further comprises at least one conductive signal routing layer 104-3 implementing a signal routing network underneath the first plurality of conductive layers 104-1, 104-2. While FIG. 2 shows an example of one conductive signal routing layer 104-3, the skilled person having benefit from the present disclosure will appreciate that also more conductive signal routing layers may be employed in actual implementations. The conductive signal routing layer 104-3 comprises a signal routing network with first routing traces (antenna feedlines) for the first polarization and second routing traces (antenna feedlines) for the second polarization. The routing traces of the signal routing network may electrically connect respective antenna feeds to other RF circuits, e.g., to beamforming networks and/or to RFICs.

Between the conductive layers 104-1, 104-2, 104-3, AiP device 100 may comprise dielectric substrate layers 106-1, 106-2 (e.g., such as a PCB pre-preg or PCB Core). AiP device 100 may also comprise a solder-down assembly underneath the layer stack 104-1, 104-2, 104-3 and configured to provide electrical and mechanical connection of the AiP device 100 to substrate, such as a printed circuit board (PCB) or motherboard. Thus, on a bottom surface, AiP device 100 may comprise a plurality of solder bumps 108 to connect AiP device 100 to a PCB or motherboard, for example. The solder bumps 108 may interface with the stack of electrically conductive layers 104-1, 104-2, 104-3 via respective metal pads (not shown) on a bottom side of AiP 100. As also shown in FIG. 2, AiP device 100 may also comprises conductive vias 114 electrically connecting two or more of the conductive layers 104-1, 104-2, 104-3.

The proposed AiP 100 has its signal routing included in the package 102. Thus, no extra external wiring for the signal routing network is needed. This may save area on a PCB or motherboard.

In some implementations, the each of the antenna elements of the integrated end-fire antenna array 110 comprises, for the first polarization, a respective substrate integrated waveguide (SIW) formed in the first plurality of conductive layers 104-1, 104-2 (and dielectric layer 106-1), and, for the second polarization, a respective planar antenna structure formed in the top layer 104-1.

A SIW may be composed of a thin dielectric substrate 106-1 covered on both faces by metallic layers 104-1, 104-2. For example, the dielectric substrate 106-1 may embed two parallel rows of metallic via holes delimiting a wave propagation area. The width a of a SIW is the distance between its two via rows, which may be defined from via-center to via-center. An effective width, de, between two opposing vias may be used to characterize more precisely the wave propagation. The distance between two successive vias of the same row may be s, and the vias diameter may be denoted by d. In classical solid-walled rectangular waveguide, the general formulation of propagation involves a superposition of transverse electric (TE) and transverse magnetic (TM) modes. Each of these is associated with particular fields and currents. In the case of SIW, the thickness is so low that the cut-off frequency of TM modes is much higher than the dominant TE mode. Thus, only TE mode propagation is practically considered in SIW design. Fundamental TE mode appears above a cut-off frequency determined by half of effective width (aₑ/2).

The planar antenna structure of each of the antenna elements in the top layer 104-1 may comprise a respective patch antenna, for example. Additionally, or alternatively, the planar antenna structure of each antenna element may comprise a respective radiation slot (slit) implemented in the top layer 104-1. A slot antenna comprises metal surface, usually a flat plate, with one or more holes or slots cut out. When the cut-outs (holes or slots) are driven by an applied RF voltage source, the cut-outs may radiate electromagnetic waves. A skinny-and-long rectangular slot antenna is a complementary structure to a planar electric dipole antenna. The skinny-and-long rectangular slot antenna is also referred as a magnetic dipole. The shape and size of the slot, as well as the driving frequency, determine the radiation pattern. Slot antennas may be used at UHF and microwave frequencies at which wavelengths are small enough that the metal plate and slot are conveniently small. Multiple slots may act as a directive array antenna and can emit a narrow fan-shaped beam of microwaves. The respective radiation slots of end-fire antenna array 110 may have a longitudinal extension in y-direction, which will be explained below.

FIG. 3 shows a schematic cross section of an AiP device 100 according to another example of the present disclosure.

The AiP device 100 illustrated in FIG. 3 comprises a stack of six electrically conductive layers 104-1 to 104-6 (L1-L6). The upper three electrically conductive (metal) layers L1-L3 implement four antenna elements 112-1 to 112-4 of a 1×4 at least dual-polarized integrated end-fire antenna array 110. The antenna elements 112-1 to 112-4 are placed parallel to each other along an axis of the antenna array 110. Here, the axis of the antenna array 110 is parallel to the x-direction. Each of the four antenna elements 112-1 to 112-4 comprises a respective SIW for z-polarization and a respective radiation slot for x-polarization (perpendicular to the radiation axis of the antenna array 110). The respective SIWs of the antenna elements 112-1 to 112-4 are formed between metal layers L1 and L3. The radiation slots of the antenna elements 112-1 to 112-4 are formed in the top metal layer L1. Metal layer L2 between layers L1 and L3 contains respective feedlines and vias for the antenna elements 112-1 to 112-4 of SIW-slot end-fire antenna array 110. Metal layer L3 forms a ground plane of the SIW-slot end-fire antenna array 110 and for the signal routing traces in metal layer L4, which contains signal routing traces (feedlines) for both polarizations (z-polarization and x-polarization) in a single layer. Metal layer L5 acts as ground plane for the signal routing traces (feedlines) of layer L4 and for two planar beamforming networks (BFNs) formed in bottom metal layer L6. That is, an upper layer L5 of the conductive layers L5 and L6 underneath the signal routing layer L4 may form a ground plane for the signal routing layer L4 and a lower layer L6 of the conductive layers L5 and L6 underneath the signal routing layer L4 may implement a planar first and a second beamforming network 120-1, 120-2.

Thus, in the illustrated example of FIG. 3, the AiP device 100 comprises a plurality of further conductive layers 104-5, 104-6 (L5, L6) underneath the signal routing layer 104-4 (L4). The plurality of further conductive layers 104-5, 104-6 (L5, L6) implement a first planar BFN 120-1 for the first polarization (e.g., z-polarization) and coupled to the plurality of antenna elements 112-1 to 112-4 via respective routing traces. The plurality of further conductive layers 104-5, 104-6 (L5, L6) also implement a second planar BFN 120-2 for the second polarization (e.g., x-polarization) and coupled to the plurality of antenna elements 112-1 to 112-4 via respective routing traces. The conductive signal routing layer 104-4 (L4) is configured to electrically couple the first and second BFNs 120-1, 120-2 to the respective antenna elements 112-1 to 112-4.

As BFNs, two compact planar Butler matrices 120-1, 120-2, one for z-polarization and one for x-polarization, may be implemented the bottom layer L6. A Butler matrix (BM) is a beamforming network used to feed a phased array of antenna elements 112-1 to 112-4. Here, the phased array is SIW-slot end-fire antenna array 110. The purpose of the Butler matrix is to control the direction of a beam, or beams, of radio transmission. It consists of an n×n matrix (n being some power of two) with hybrid couplers and fixed-value phase shifters at the junctions. The device has n input ports (the beam ports) to which power is applied, and n output ports (the antenna element ports) to which n antenna elements are connected (here: n=4 as four antenna elements are used). The Butler matrix feeds power to the antenna elements 112-1 to 112-4 with a (constant) phase difference between elements 112-1 to 112-4 such that the beam of radio transmission is in the desired direction. A combination of hybrid couplers and fixed-value phase shifters may be used to build a Butler matrix.

The example layer stack of AiP 100 schematically shown in FIG. 3 will be described in more detail below.

An AiP 100 with six conductive layers 112-1 to 112-6 (L1-L6) is assumed and its stack-up and layer thickness are summarized in Table 1.

TABLE 1

| Structure | Material | Thickness | |
|---|---|---|---|
| Antenna | Copper | 15 | um |
| array | Substrate | 390 | um |
| | Copper | 15 | um |
| | Substrate | 430 | um |
| | Cooper | 15 | um |
| Routing | Substrate | 60 | um |
| | Cooper | 15 | um |
| | Substrate | 60 | um |
| BM | Cooper | 15 | um |
| | Substrate | 60 | um |
| | Copper | 15 | um |

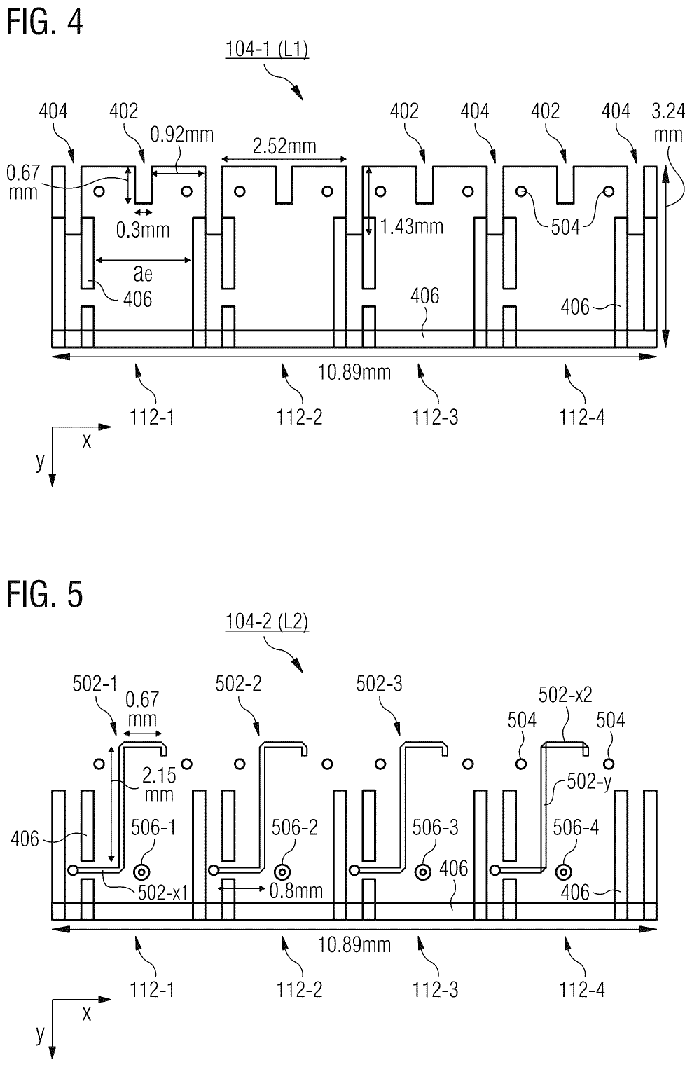

Overall geometry, dimension, and layout of each layer for the example dual-polarized antenna array architecture are shown in FIGS. 4 to 9. Please note that the proposed architecture not only can be implemented by using chip scale packing technology, but also by glass-based package, LTCC (Low Temperature Cofired Ceramic), and HTCC (High Temperature Cofired Ceramic) technologies.

The proposed AiP 100 comprises a layer stack comprising the integrated end-fire antenna array 110 in the upper layers, signal routing between BFNs and end-fire antenna array 110 in the middle layer(s), and the BFNs 120-1, 120-2 in the bottom layers.

Metal layer 104-1 (L1) may have a thickness (in z-direction) of 15 μm. Dielectric layer 106-1 underneath Metal layer 104-1 (L1) may have a thickness (in z-direction) of 390 μm. Metal layer 104-2 (L2) underneath dielectric layer 106-1 may have a thickness (in z-direction) of 15 μm. Dielectric layer 106-2 underneath metal layer 104-2 (L2) may have a thickness (in z-direction) of 430 μm. Metal layer 104-3 (L3) underneath dielectric layer 106-2 may have a thickness (in z-direction) of 15 μm. Dielectric layer 106-3 underneath metal layer 104-3 (L3) may have a thickness (in z-direction) of 60 μm. Metal layer 104-3 (L4) underneath dielectric layer 106-3 may have a thickness (in z-direction) of 15 μm. Dielectric layer 106-4 underneath metal layer 104-4 (L4) may have a thickness (in z-direction) of 60 μm. Metal layer 104-5 (L5) underneath dielectric layer 106-4 may have a thickness (in z-direction) of 15 μm. Dielectric layer 106-5 underneath metal layer 104-5 (L5) may have a thickness (in z-direction) of 60 μm. Bottom metal layer 104-6 (L6) underneath dielectric layer 106-5 may have a thickness (in z-direction) of 15 μm. The skilled person having benefit from the present disclosure will appreciate that the illustrated thicknesses are merely an example and may be different, depending on a desired bandwidth and/or radiation characteristic of AiP 100. In general, the dielectric substrate layers may be thicker than the metal layers.

FIG. 4 shows a top view of top metal layer 104-1 (L1).

Top metal layer 104-1 (L1) spans an x-y-plane and essentially has rectangular dimensions. In the illustrated example, an extension of top metal layer 104-1 (L1) in x-direction (i.e., along the axis of antenna array 110) is 10.89 mm, and an extension in y-direction is 3.24 mm. The antenna elements 112-1 to 112-4 are arranged along an axis in x-direction. Each of the antenna elements 112-1 to 112-4 has an extension in x-direction of 2.52 mm. On an “upper” edge of top metal layer 104-1 (L1), each antenna element 112-1 to 112-4 comprises a respective radiation slot 402 in y-direction and placed in the middle between two adjacent decoupling slots 404. The radiation slots 402 each have an extension in x-direction of 0.3 mm and extend in y-direction from the “upper” edge of top metal layer L1 by 0.67 mm. Thus, a main longitudinal extension of the radiation slots 402 is in y-direction (perpendicular to the axis of the antenna array 110). The distance in x-direction between the radiation slot 402 and adjacent decoupling slots 404 is 0.92 mm. On the “upper” edge of top metal layer 104-1 (L1), adjacent antenna elements 112 are separated by respective decoupling slots 404 to improve isolation. The decoupling slots 404 between adjacent antenna elements each have an extension in x-direction of 0.38 mm and extend in y-direction (perpendicular to the axis of the antenna array 110) from the “upper” edge of top metal layer L1 by 1.43 mm. The skilled person having benefit from the present disclosure will appreciate that the illustrated dimensions are merely an example and may be different, depending on a desired bandwidth and/or radiation characteristic of AiP 100.

Reference signs 406 indicate parallel rows of metallic vias (in z-direction) in dielectric layer 106-1 and delimiting a wave propagation area of the respective SIWs of the antenna elements 112-1 to 112-4. The effective width aₑ may be used to characterize more precisely the wave propagation of the SIWs. With this effective width, the propagation constant of a SIW is similar to that of a classical rectangular waveguide whose width is de.

FIG. 5 shows a top view of second metal layer 104-2 (L2).

Metal layer L2 below top metal layer L1 implements respective antenna feeds for each polarization. Feedlines 502 in metal layer L2 may be used as antenna feeds for respective radiation slots 402 in metal layer L1. Each feedline 502 comprises an axial inner portion 502-x1 extending 0.8 mm in x-direction, a portion 502-y extending 2.15 mm in y-direction from the inner portion 502-x1 to an axial outer portion 502-x2 extending 0.67 mm in x-direction. The portions 502-x1, 502-y, and 502-x2 of feedline 502 are integrally formed in metal layer L2. Each feedline 502 in metal layer L2 capacitively couples to the respective radiation slot 402 in metal layer L1. The axial outer portion 502-x2 of feedline 502 may actually emit millimeter-waves in a third radiation mode in y-direction (e.g., triple radiation-mechanism antenna array 110). Due to the “triple radiation mechanism”, slot 402 plus feedline 502-x2 may create a titled beam with an extended beamwidth feature.

Each antenna element 112 further comprises a first and a second vertical via 504 having a longitudinal extension in z-direction and connecting metal layer L3 and metal layer L1. The first and the second vertical vias 504 are arranged (in x-direction) symmetrically on opposite sides of the respective radiation slot 402. The vias 504 may work as “top-hat” dipoles and may increase bandwidth and beamwidth for vertical polarization (in z-direction). As indicated by reference signs 506, each antenna element 112-1 to 112-4 also comprises a respective probe via 506 going from metal layer L3 to metal layer L2 and used to excite the respective SIW (i.e., vertical polarization).

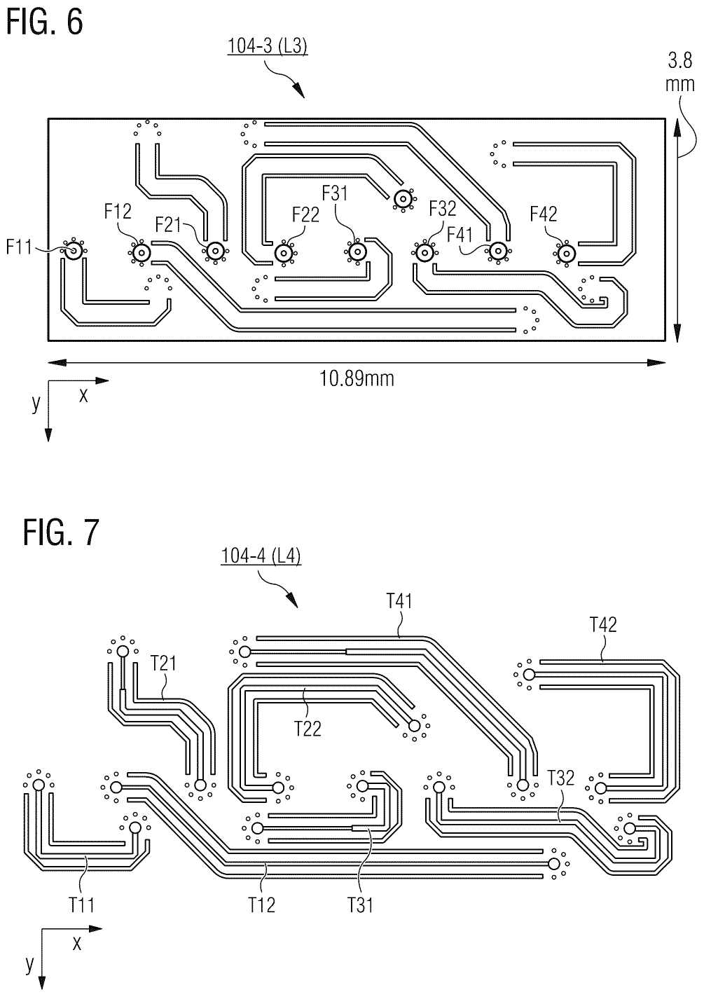

FIG. 6 shows a top view of third metal layer 104-3 (L3).

Metal layer L3 acts as ground plane of the antenna array 110. In the illustrated example, an extension of metal layer L3 in x-direction is 10.89 mm, and an extension in y-direction is 3.8 mm. Note that L3 length in y direction is 3.8 mm which is longer than 3.24 mm of L1 GND in FIG. 4. These asymmetric GND lengths y direction may enable a titled beam for SIW. Metal layer L3 comprises through holes for antenna feedings vias. The feeding vias comprise a first feeding via F11 connecting to feedline 502-1 of the first antenna element 112-1. Feedline 502-1 is used to excite radiation slot 402 of the first antenna element 112-1. The feeding vias comprise a second feeding via F12 connecting to probe via 506-1 of the first antenna element 112-1. Probe via 506-1 is used to excite the SIW of the first antenna element 112-1. The feeding vias comprise a third feeding via F21 connecting to feedline 502-2 of the second antenna element 112-2. Feedline 502-2 is used to excite radiation slot 402 of the second antenna element 112-2. The feeding vias comprise a fourth feeding via F22 connecting to probe via 506-2 of the second antenna element 112-2. Probe via 506-2 is used to excite the SIW of the second antenna element 112-2. The feeding vias comprise a fifth feeding via F31 connecting to feedline 502-3 of the third antenna element 112-3. Feedline 502-3 is used to excite radiation slot 402 of the third antenna element 112-3. The feeding vias comprise a sixth feeding via F32 connecting to probe via 506-3 of the third antenna element 112-3. Probe via 506-3 is used to excite the SIW of the third antenna element 112-3. The feeding vias comprise a seventh feeding via F41 connecting to feedline 502-4 of the fourth antenna element 112-4. Feedline 502-4 is used to excite radiation slot 402 of the fourth antenna element 112-3. The feeding vias comprise an eighth feeding via F42 connecting to probe via 506-4 of the fourth antenna element 112-4. Probe via 506-4 is used to excite the SIW of the fourth antenna element 112-4.

The radiation direction of the SIWs (z-polarized) is in y axis. The radiation direction of the slots 402 (x-polarized) is mainly in z axis and some in y axis because the slots 402 are located at the edge of L1. The radiation direction of slot feeds 502-x2 (x-polarization) is in y direction. Thus, both slots 402 on L1 and slot feeds 502-x2 on L2 have x polarization and extend the beamwidth in z-y plane with a tilted beam feature. SIW radiation beam can be also tilted toward z direction if L3 GND layer 104-3 is slightly longer in y-direction than L1 & L2 layers (L4-L6 do not need to be longer), i.e. asymmetric GND length. The main excitation structure for the SIWs are the vertical vias 506 between L1 and L3. Main radiation power is toward y direction for SIW while main radiation power direction of slots 402 is between y direction and z direction.

FIG. 7 shows a top view of fourth metal layer 104-4 (L4).

Metal layer L4 provides conductive signal routing traces for both polarizations, z-polarization and x-polarization in a single metal layer. The signal routing traces comprise a first signal routing trace T11 connecting a first output port of the beamforming network (BFN) for x-polarization to feedline 502-1 of the first antenna element 112-1 via first feeding via F11. The signal routing traces comprise a second signal routing trace T12 connecting a first output port of the beamforming network (BFN) for z-polarization to probe via 506-1 of the first antenna element 112-1 via second feeding via F12. The signal routing traces comprise a third signal routing trace T21 connecting a second output port of the beamforming network (BFN) for x-polarization to feedline 502-2 of the second antenna element 112-2. The signal routing traces comprise a fourth signal routing trace T22 connecting a second output port of the beamforming network (BFN) for z-polarization to probe via 506-2 of the second antenna element 112-2. The signal routing traces comprise a fifth signal routing trace T31 connecting a third output port of the beamforming network (BFN) for x-polarization to feedline 502-3 of the third antenna element 112-3. The signal routing traces comprise a sixth signal routing trace T32 connecting a third output port of the beamforming network (BFN) for z-polarization to probe via 506-3 of the third antenna element 112-3. The signal routing traces comprise a seventh signal routing trace T41 connecting a fourth output port of the beamforming network (BFN) for x-polarization to feedline 502-4 of the fourth antenna element 112-4. The signal routing traces comprise an eighth signal routing trace T42 connecting a fourth output port of the beamforming network (BFN) for z-polarization to probe via 506-4 of the fourth antenna element 112-4.

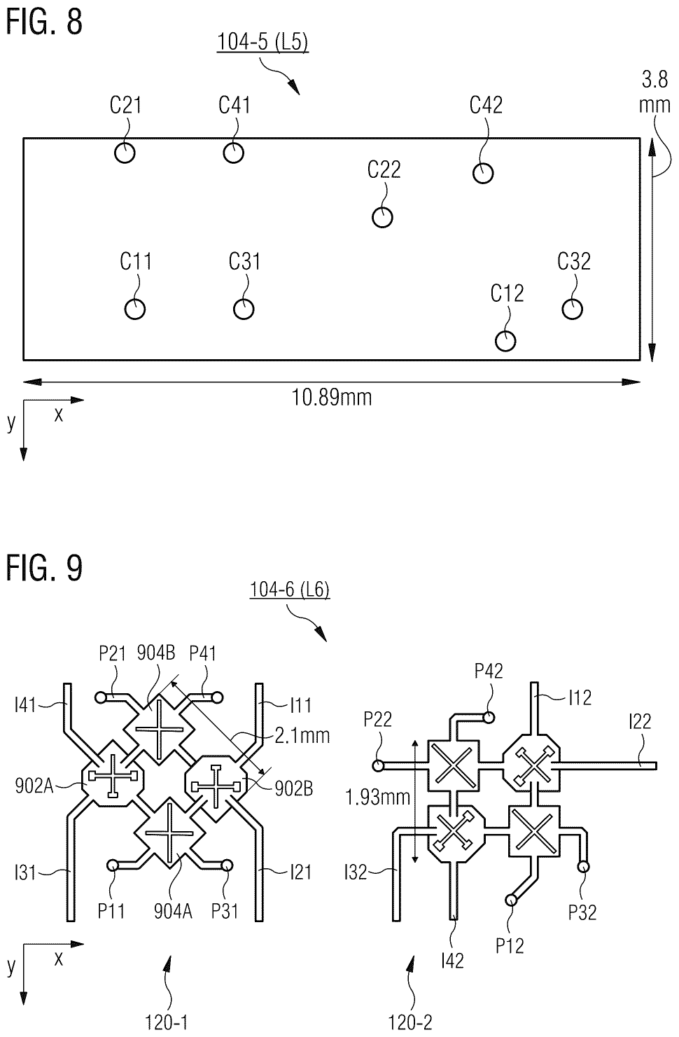

FIG. 8 shows a top view of fifth metal layer 104-5 (L5).

Metal layer L5 acts as ground plane of the signal routing network of layer L4. In the illustrated example, an extension of metal layer L5 in x-direction is 10.89 mm, and an extension in y-direction is 3.8 mm. Metal layer L5 comprises through holes for connecting vias between BFN output ports and antenna feedlines. The connecting vias comprise a first connecting via C11 connecting a first output port of the beamforming network (BFN) for x-polarization to signal routing trace T11 and hence feedline 502-1 of the first antenna element 112-1. Feedline 502-1 is used to excite radiation slot 402 of the first antenna element 112-1. The connecting vias comprise a second connecting via C21 connecting a second output port of the beamforming network (BFN) for x-polarization to signal routing trace T21 and hence feedline 502-2 of the second antenna element 112-2. Feedline 502-2 is used to excite radiation slot 402 of the second antenna element 112-2. The connecting vias comprise a third connecting via C31 connecting a third output port of the beamforming network (BFN) for x-polarization to signal routing trace T31 and hence feedline 502-3 of the third antenna element 112-3. Feedline 502-3 is used to excite radiation slot 402 of the third antenna element 112-3. The connecting vias comprise a fourth connecting via C41 connecting a fourth output port of the beamforming network (BFN) for x-polarization to signal routing trace T41 and hence feedline 502-4 of the fourth antenna element 112-4. Feedline 502-4 is used to excite radiation slot 402 of the fourth antenna element 112-4. The connecting vias comprise a fifth connecting via C12 connecting a first output port of the beamforming network (BFN) for z-polarization to signal routing trace T12 and hence probe via 506-1 of the first antenna element 112-1. Probe via 506-1 is used to excite the SIW of the first antenna element 112-1. The connecting vias comprise a sixth connecting via C22 connecting a second output port of the beamforming network (BFN) for z-polarization to signal routing trace T22 and hence probe via 506-2 of the second antenna element 112-2. Probe via 506-2 used to excite the SIW of the second antenna element 112-2. The connecting vias comprise a seventh connecting via C32 connecting a third output port of the beamforming network (BFN) for z-polarization to signal routing trace T32 and hence probe via 506-3 of the third antenna element 112-3. Probe via 506-3 3 is used to excite the SIW of the third antenna element 112-3. The connecting vias comprise an eighth connecting via C42 connecting a fourth output port of the beamforming network (BFN) for z-polarization to signal routing trace T42 and hence probe via 506-4 of the fourth antenna element 112-4. Probe via 506-4 is used to excite SIW of the fourth antenna element 112-4.

FIG. 9 shows a top view of sixth metal layer 104-6 (L6).

FIG. 9 illustrates a sixth layer of the layer stack-up including a set of Butler matrix blocks, in accordance with the present disclosure. Again, as shown in FIG. 9, metal layer L6 comprises the two Butler matrix blocks 120-1, 120-2, each comprising a respective set of input ports I11-I41, I12-I42 and output ports P11-P41, P12-P42. Butler matrix 120-1, 120-2 comprises any suitable number n of beam-selection input ports (I11-I41, I12-I42), and any suitable number n of output ports (P11-P41, P12-P42), with n being equal to the number of antenna elements 112 in the antenna array 110. Thus, in the non-limiting and illustrative scenario in which the antenna array 110 comprises four antenna elements 112, as shown in FIG. 3, each Butler matrix 120-1, 120-2 comprises four input ports and four output ports, as shown in FIG. 9.

Again, a Butler matrix is a type of passive beamforming network that is used to feed an array of antenna elements. Thus, the Butler matrix blocks 120-1, 120-2 control the direction of a beam, or beams, for a radio transmission. To do so, each Butler matrix 120-1, 120-2 is coupled to a set of beam selection input ports I11-I41 and I12-I42, which are accessed during transmission (i.e. driven) and reception (received and the signals combined, when applicable), and a set of output ports P11-P41 and P12-P42, to which each of the antenna elements 112 are connected via the respective antenna feeds 502, 506 and the signal routing network of metal layer L4 as discussed herein.

The Butler matrix blocks 120-1, 120-2 thus function to couple signals between the antenna elements 112 during transmission and reception to provide a phase difference between the antenna elements 112, such that the beam of radio transmission (or reception) is in the desired direction. The beam direction is controlled by in this way switching access to the desired beam port. Using the transmission case as one illustrative scenario, as a transmission signal is applied to one of the beam-selection input ports I11-I41 and I12-I42, the antenna array of antenna elements 112 transmits in accordance with a radiation pattern having a predetermined beam direction corresponding to that particular activated beam selection input port. Thus, by selectively coupling transmission signals to each of the beam-selection input ports, the beam direction of the antenna array of antenna elements 112 is changed to match one of a set of predetermined beam directions. Any combination of the beam-selection input ports, or all beam-selection input ports, may be accessed simultaneously or sequentially in this way to provide different phase tapers across the antenna elements 112 in the antenna array 110, resulting in various combinations of predetermined radiation patterns and/or predetermined beam directions.

To perform such beam control, each Butler matrix block 120-1, 120-2 comprises two 45-degree hybrid patch couplers 902A, 902B, which function to split (such as a −3 dB split) the signals at the respective beam-selection input ports into two signals having a 45-degree phase offset relationship with one another. The input ports are isolated from one another due to the shape of each hybrid patch coupler 902A, 902B. The output of each of the 45-degree hybrid patch couplers 902A, 902B (i.e. the non-input ports) are in turn fed into each one of two quadrature hybrid slotted patch couplers 904A, 904B. Each quadrature hybrid slotted patch coupler 904A, 904B functions to further split (such as a −3 dB split) the respectively received signals into two signals having a 90-degree phase offset relationship with one another. The input ports of each quadrature hybrid slotted patch coupler 904A, 904B (i.e. the non-output ports) are also isolated from one another due to the shape of each quadrature hybrid slotted patch coupler 904A, 904B. Of course, the number of 45-degree hybrid patch couplers 902 and quadrature hybrid slotted patch couplers 904 is a function of the number n of input and output ports that are implemented, with the number of each being n/2.

Again, each one of the output ports P11-P41, P12-P42 of each Butler matrix 120-1, 120-2 is coupled to a respective conductive trace that is part of the signal routing network, which is disposed on layer 4 (L4) of the AiP 100 as shown in FIG. 3.

Turning again to FIG. 7, the signal routing network of metal layer L4 is shown in further detail, with each of the output ports P11-P41, P12-P42 of each Butler matrix block 120-1, 120-2, respectively, being mapped to a respective conductive trace T11-T41, T12-T42 associated with each antenna feed. Because equal-length signal routing would demand extra package layers, the proposed dual-polarized beam-switching end-fire antenna array integrates the signal routing traces T11-T41, T12-T42 in a single metal layer (L4), resulting in different lengths of feed lines for the same polarization and causing frequency-dependent beam tilting/shifting over an operational frequency range (e.g. 57-71 GHz). Thus, the conductive signal routing layer L4 may be a single layer spanning an x-y-plane and comprising feedlines T11-T41, T12-T42 of different physical lengths for different antenna elements 112 of array 110. For example, the feedline T12 for the SIW (vertical polarization) of the first antenna element 112-1 may have a different length (e.g., may be longer) than feedline T42 for the SIW of the fourth antenna element 112-4. Further, feedline T11 for the radiation slot 402 (horizontal polarization) of the first antenna element 112-1 may have a different physical length (e.g., may be longer) than feedline T41 for the radiation slot 402 of the fourth antenna element 112-4.

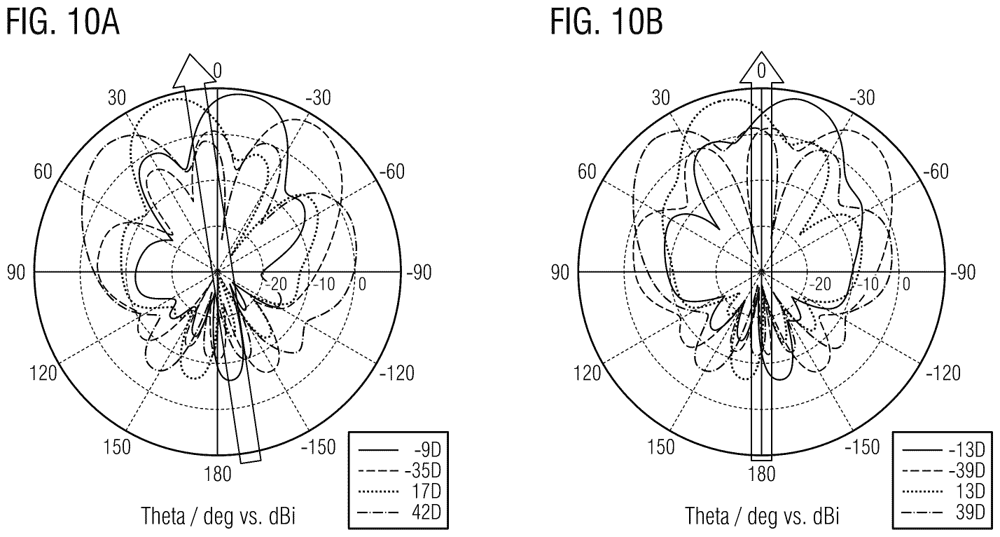

The beam tilting/shifting may be corrected or leveraged to address usage scenarios. When symmetric feed-line pairs (e.g., pair 1: Lines T11 & T41 and pair 2: Lines T21 & T31) are matched to the same electrical length, the beam shifting effect over frequency range can be corrected. For example, as shown in FIG. 7, line T11 is the feed for horizontal polarization of antenna element 112-1. Line T41 is the feed for horizontal polarization of antenna element 112-4, which is the physically longest feed. When both line T11 and line T41 have, for example, 45° in electrical length, a 5° beam tilt (shown in FIG. 10A) can be corrected to 0° (shown in FIG. 10B).

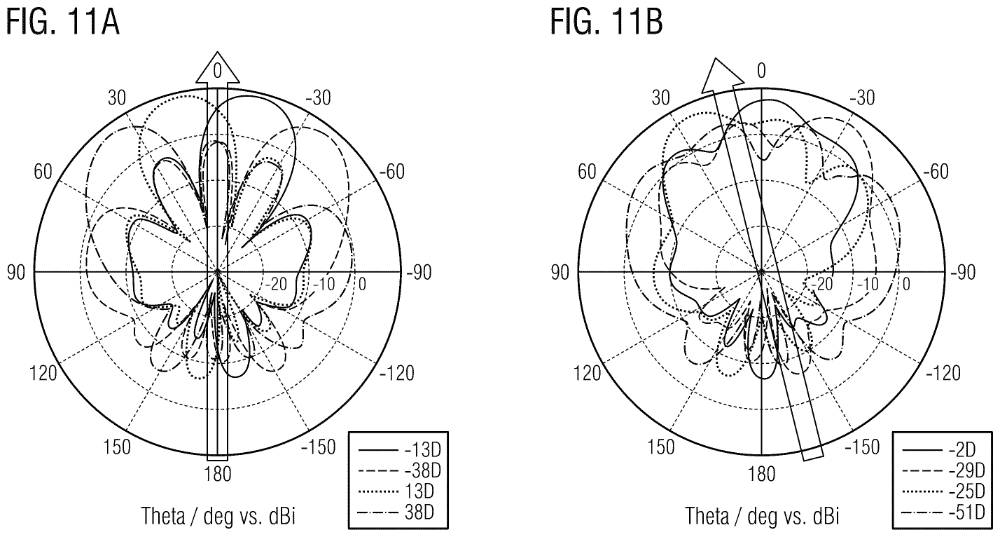

This approach allows flexible control of the beam shifting in azimuth plane, as well as symmetric beam steering without equal physical length matching in all feed lines which would increase the total surface area of the package (thus cost increase). On the other hand, one can tilt the beam in azimuth plane for both polarizations on purpose to reconfigure the beam. Assume that all feed lines have the same physical length. Then, there is no beam shift (shown in FIG. 11A). When one feedline is physically longer and the other three lines remain the same physically length in the routing layer (L4), it is observed that the steering beams can be tilted, for example, from 0° to 10° (shown in FIG. 11B) as the phase difference/electrical length of the longest feedline and the others changes from 0° to 125°.

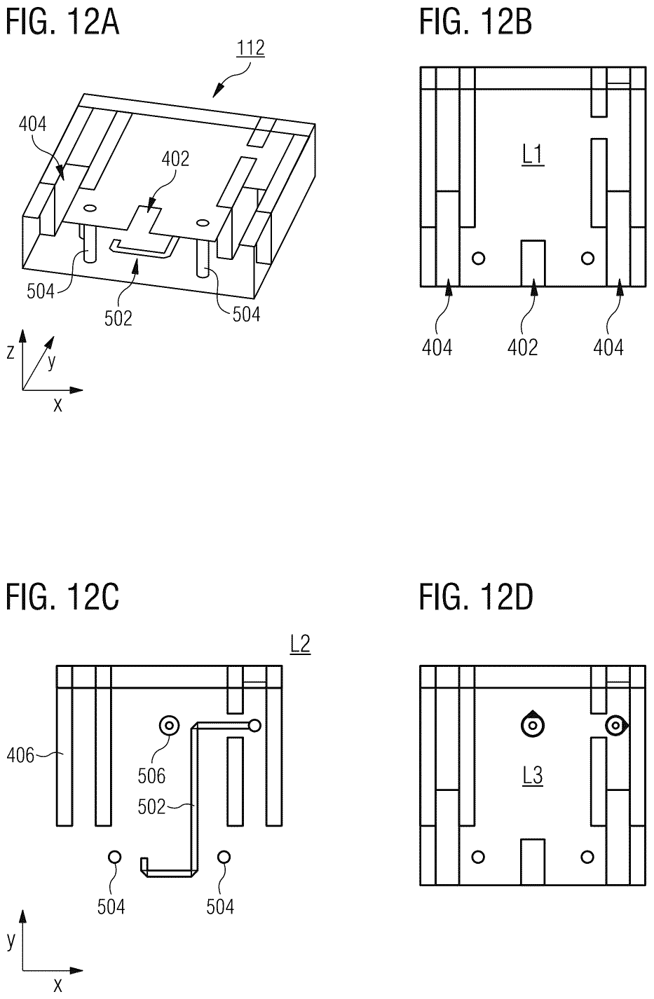

FIGS. 12A-12D illustrate the geometry of a single SIW-slot antenna element 112.

Each SIW-slot element antenna element 112 comprises a first plurality of conductive layers 104-1 (L1) to 104-3 (L3) forming antenna element of end-fire antenna array 110. Each antenna element 112 is configured for a first polarization (e.g., SIW) and for a second polarization (e.g., slot 402). FIG. 12A shows the overall 3-D structure of SIW-slot antenna element 112, FIG. 12B shows top metal layer (L1) of SIW-slot antenna element 112, FIG. 12C shows middle metal layer with feeds (L2) SIW-slot antenna element 112, and FIG. 12D shows bottom metal layer (L3) of SIW-slot antenna element 112.

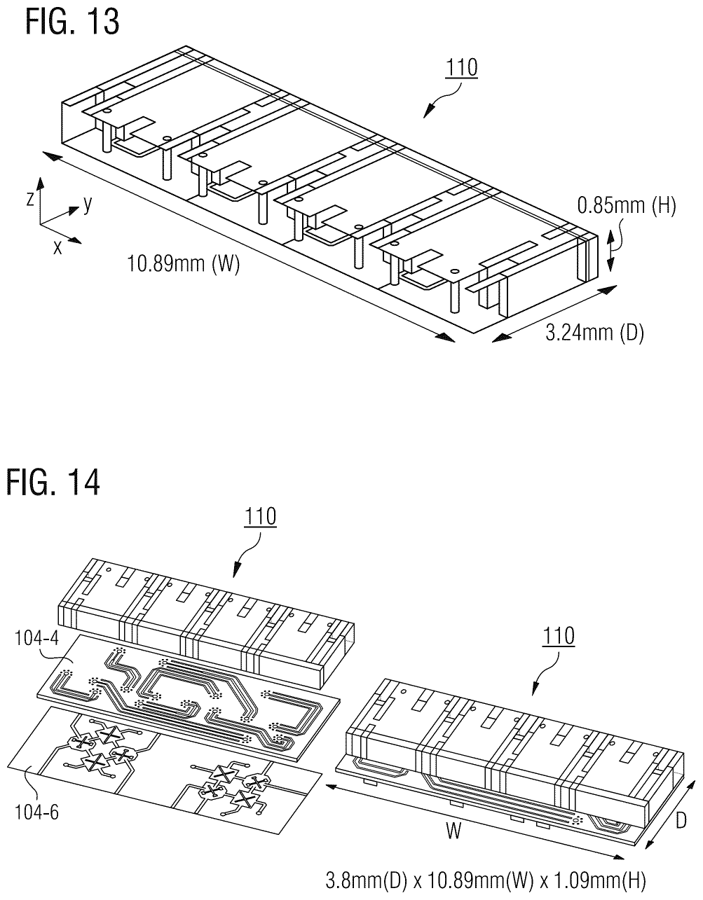

The resulting 1×4 SIW-slot antenna array 110 with four SIW-slot element antenna elements 112-1- to 112-4 is shown in FIG. 13. In one example implementation, the SIW-slot end-fire antenna array 110 has a dimension of 10.89 mm in x-direction, 3.24 mm in y-direction, and 0.85 mm in z-direction. Thus, the proposed dual-polarized SIW-slot antenna array 110 may be of compact design and may be useful to be integrated in mobile computing devices, such as laptops, tablets, or smartphones, for example. If negative y-direction dimension of the bottom layer (L3) is extended, the maximum radiation direction of SIW changes from negative y-axis direction to the direction between negative y axis and positive z axis (i.e. titled vertically polarized beam toward z axis).

The proposed compact and wideband dual-polarized beam-switching end-fire array architecture in AiP (Antenna-in-Package) can be implemented in a cost-effective 6-layer PCB or package, including antenna array, signal routing, and beamforming networks stacked on top of each other. A dual polarized antenna element 112 utilizes SIW aperture for vertical polarization (z-direction) and slot antenna for horizontal polarization (x-direction). Substrate metal layers L1-L3 are used to build the dual-linearly-polarized 1×4 array with the SIW-slot element antenna configuration. The SIW structure is mainly constructed by L1 and L3, and a probe via 506 is used to excite vertical polarization, going from L3 to L2. Meanwhile, the radiation slot 402 is located in the top metal layer (L1) of the SIW structure, and the feedline 502 for slot excitation of horizontal polarization is in the middle layer (L2) of the SIW structure. Additionally, decoupling slots 404 are located between the neighboring antenna elements 112 to improve isolation. Two vias 504 are added at the end of the antenna aperture by each side of the radiation slot 402 to work as “top hat” dipoles and increase bandwidth and beamwidth for vertical polarization.

The routing layer (L4) connecting the array 112 and BFNs 120 may be a stripline structure that takes L3-L5 (see FIG. 3), utilizing antenna bottom layer (L3) as top ground plane and BFN top layer (L5) as bottom ground plane, which has effectively saved the total space. Two compact BFNs 120-1, 120-2 are located at the bottom layer (L6) to support switching beams for both polarizations. One BFN has 45-degree coupler, and one has 90-degree coupler, to avoid crossover and 45-degree phase shifters in the routing layer. Vias may be used to connect the output ports of dual compact BFNs 120-1, 120-2 from the bottom layer (L6) to routing layer (L4), and from routing layer (L4) to antenna feeding layer (L2) to excite dual polarizations.

The resulting AiP 100 shown in FIG. 14 can support 57-71 GHz frequency range which covers the entire 60 GHz-ISM bands to cover the world with a single stock keeping unit (SKU) product. By using SIW with “top-hat” dipoles and edge-located slot, the antenna array AiP 100 can achieve wide angular coverage in both polarizations.

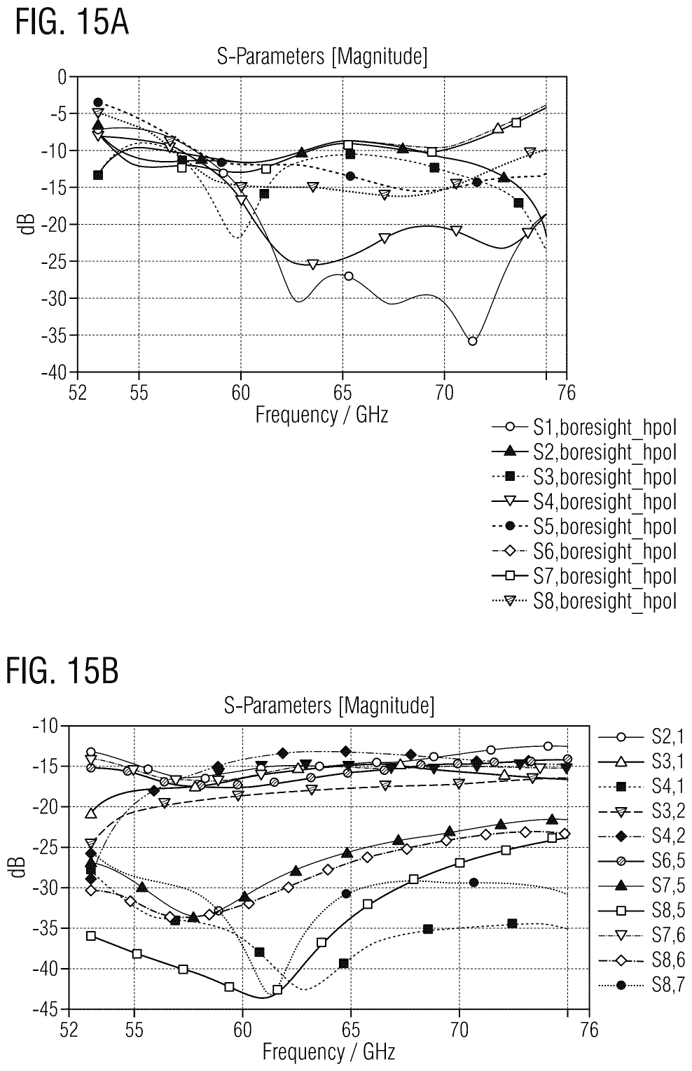

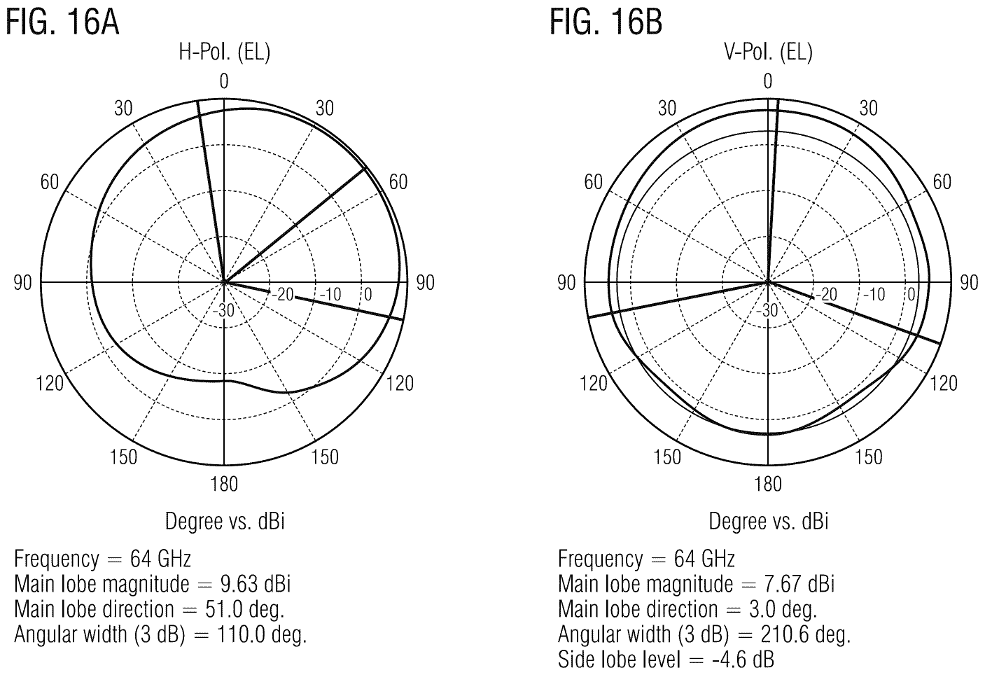

Simulated S-parameters and radiation patterns are depicted in FIG. 15 and FIG. 16, respectively. FIG. 15 shows simulated S-parameters of the example dual-polarized 1×4 end-fire SIW-slot antenna array 110. In particular, FIG. 15A shows the amplitude of active reflection coefficients at ideally combined simulation ports and FIG. 15B shows isolation levels between element antenna ports. FIG. 16A (horizontal polarization) and FIG. 16B (vertical polarization) show simulated realized-gain elevation radiation patterns of the example dual-polarized end-fire antenna array 110.

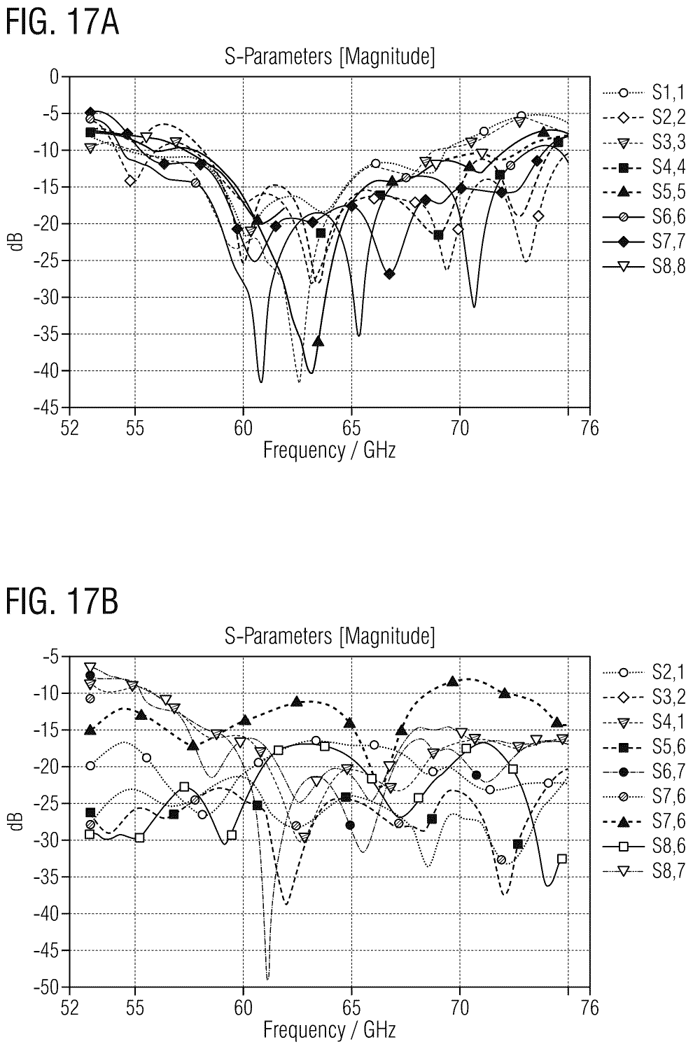

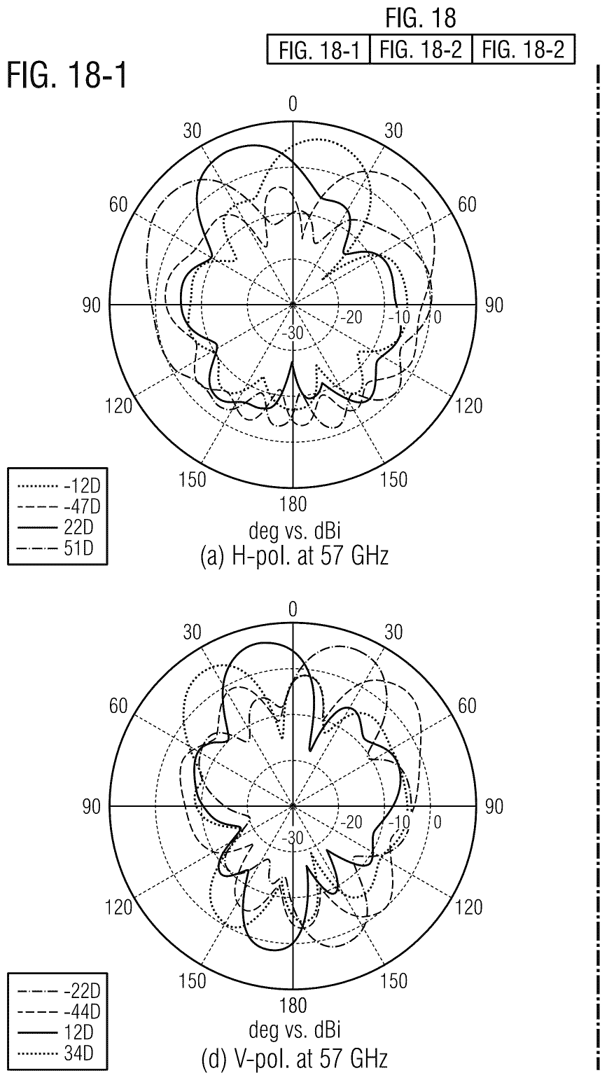

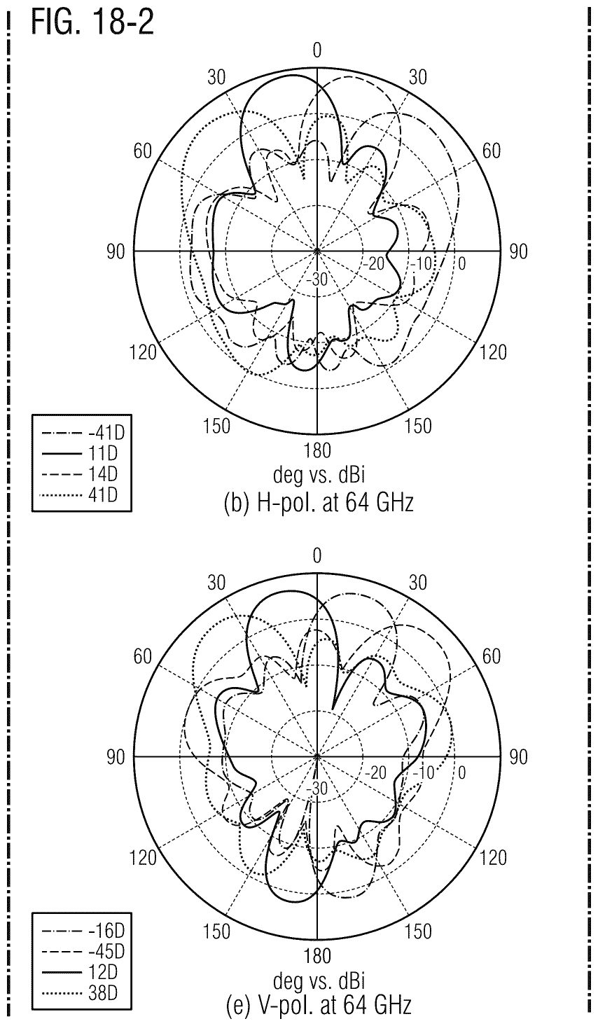

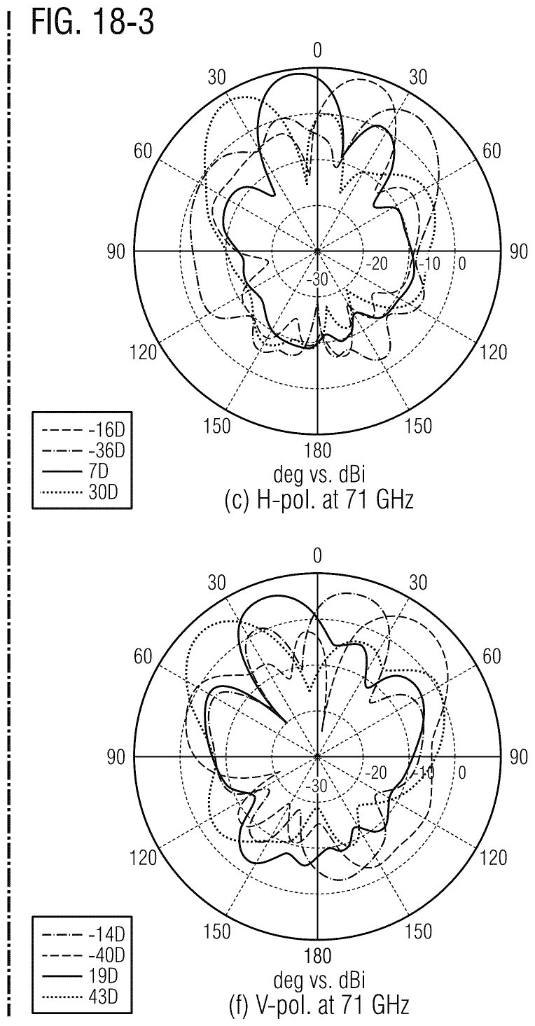

Simulated S-parameters and realized-gain azimuth radiation patterns of the BFN-integrated array AiP 100 for both horizontal and vertical polarizations are shown in FIG. 17 and FIG. 18, respectively. The performance of the example design may be further improved through optimization techniques including genetic algorithm, particle swam, and covariance matrix adaptation evolution strategy (CMA-ES).

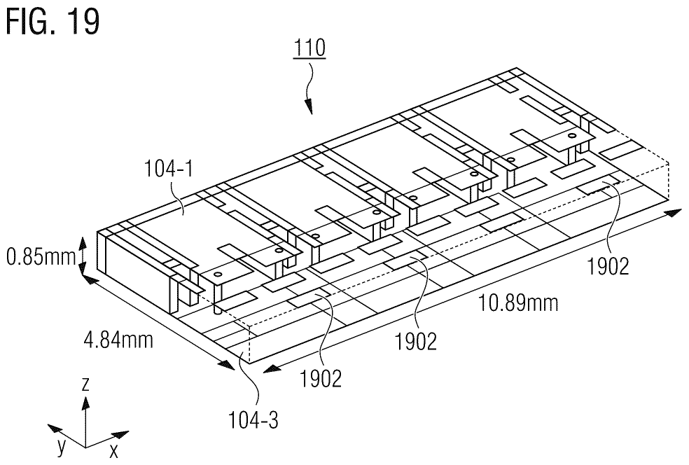

FIG. 19 illustrates a design variation of dual-polarized SIW-slot antenna array 110.

An alternative example to improve gain and F/B ratio is to add parasitic directors 1902 on the top layer 104-1 (L1) of the antenna 110. In the example of FIG. 19, the top layer 104-1 (L1) comprises a plurality of additional parasitic directors 1902 associated with the plurality of antenna elements 112. In particular, a first line of parasitic directors 1902 is arranged along an axis in x-direction in front of the plurality of antenna elements 112-1 to 112-4, more particularly in front of the respective radiating slots 402. In the example shown in FIG. 19, a second line of parasitic directors 1902 is arranged in parallel to the first line along an axis in x-direction and in front of the first line of parasitic directors 1902. The second line of parasitic directors 1902 comprises less parasitic directors 1902 than the first line of parasitic directors. Metal layer L3 is extended in negative y-direction and acts as ground plane for the modified antenna array 110. In the illustrated example of FIG. 19, an extension of metal layer L3 in x-direction is 10.89 mm, and an extension in y-direction is 4.84 mm. An extension of the antenna array 110 in z-direction is 0.85 mm. SIW radiation beam can be also tilted toward z direction if L3 GND layer 104-3 is slightly longer than L1 & L2 layers (L4-L6 do not need to be longer), i.e. asymmetric GND length. The main excitation structure for SIW is the vertical via 506 between L1 and L3.

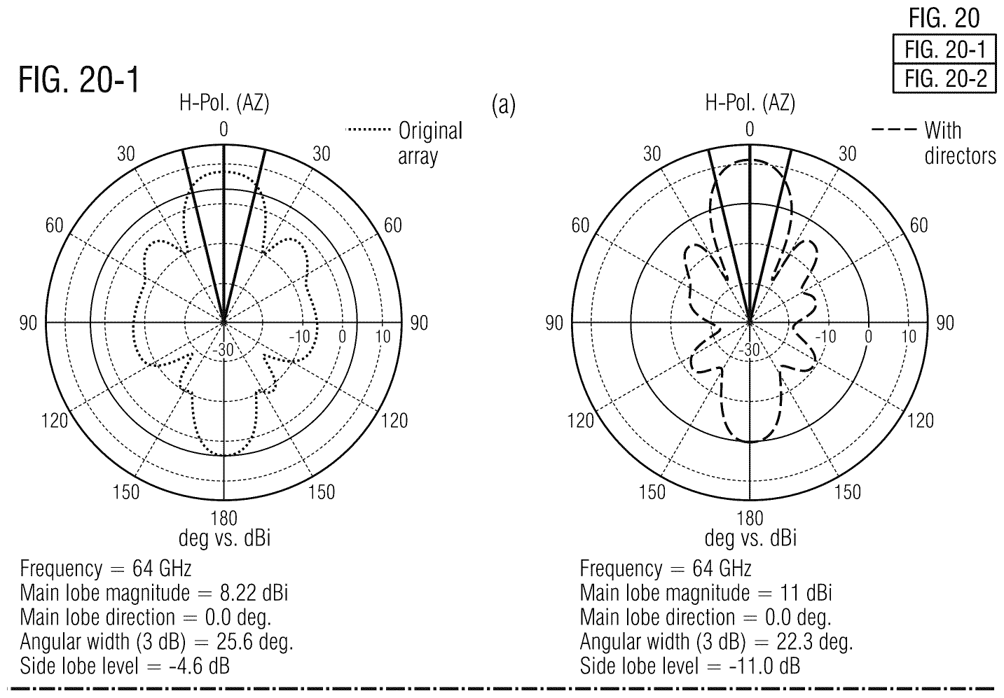

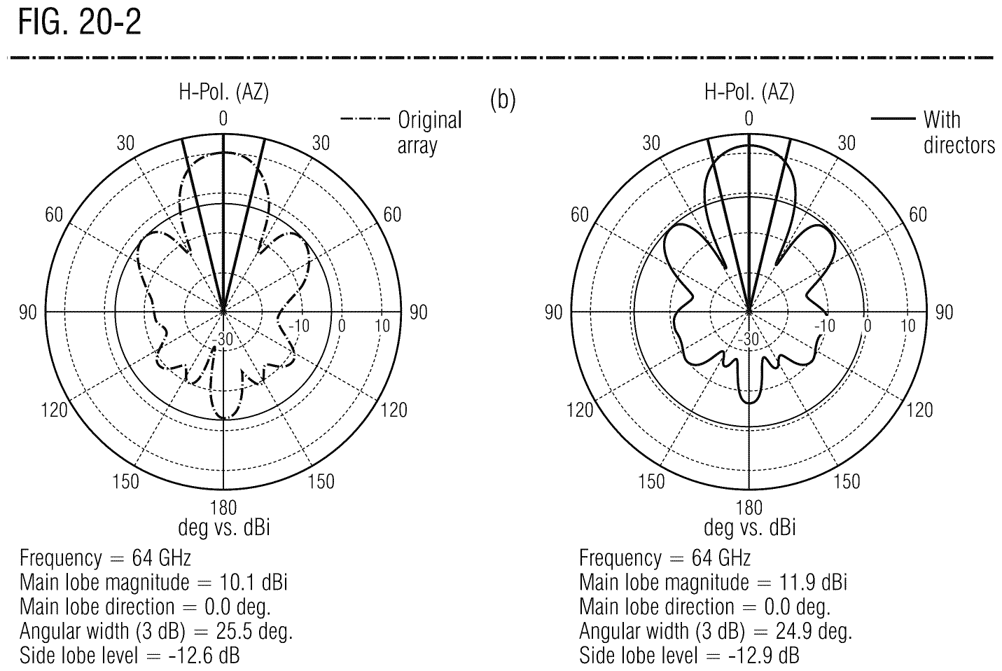

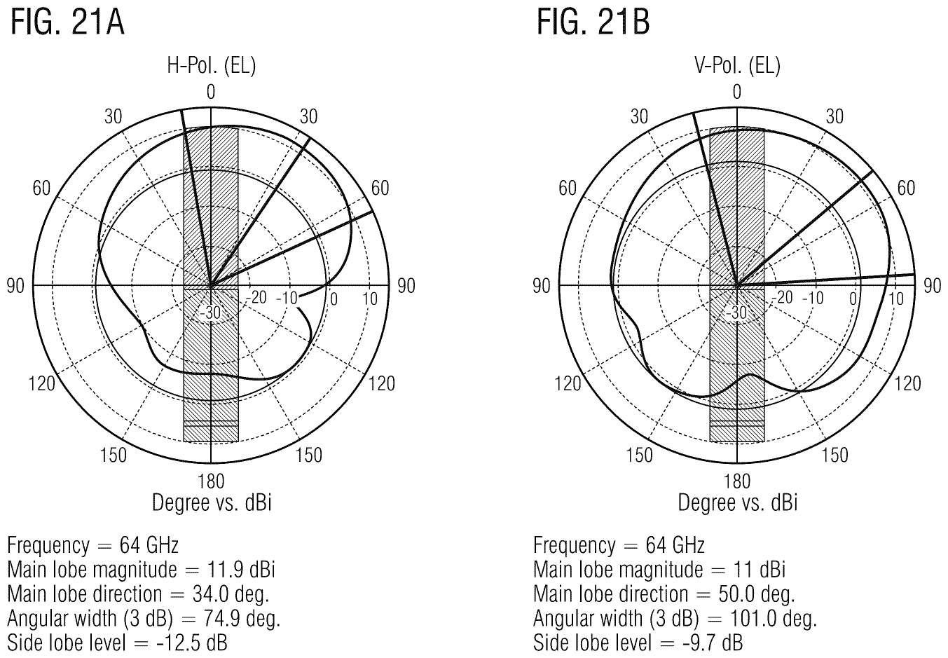

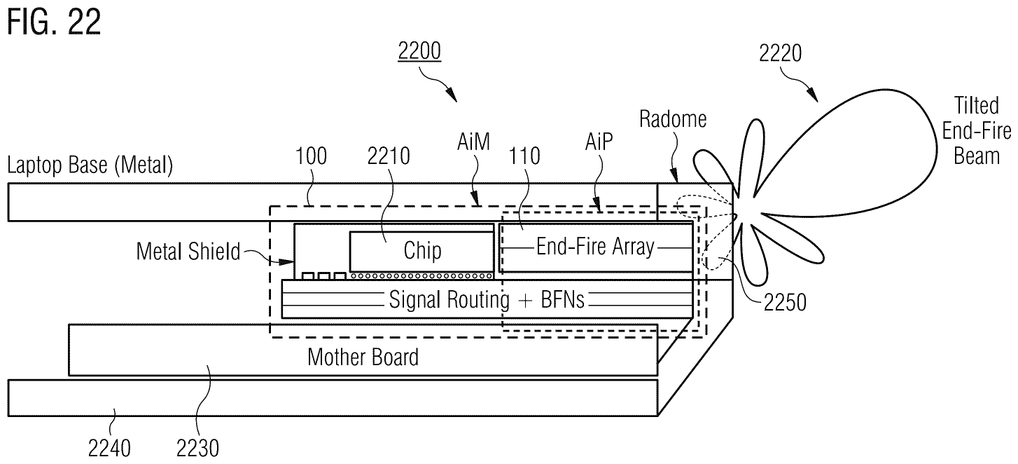

A comparison between simulated realized-gain azimuthal radiation pattern of an example design is shown in FIG. 20. It can also introduce beam tilting to both polarizations in the elevation plane due to the extended ground plane 104-3 (L3) and substrate, as shown in the simulated realized-gain elevation radiation pattern (shown in FIG. 21) based on example cases. The proposed AiP 100 may be integrated into a portable computing device, for example. FIG. 22 schematically shows a device 2200, such as a laptop, comprising AiP 100 with the end-fire antenna array 110 of any one of the previously described examples. As described above, end-fire antenna array 110 sits on one or more conductive layers comprising at least one conductive signal routing layer 104-4 underneath end-fire antenna array 110, which is implemented by a plurality of conductive layers 104-1 to 104-3 above signal routing layer 104-4. One or more RFICs 2210 (or portions thereof) are arranged laterally adjacent to the end-fire antenna array 110 on a side opposite to a radiation or reception direction 2220 of the end-fire antenna array 110. RFIC 2210 also sits on the one or more conductive layers comprising at least the conductive signal routing layer 104-4 underneath end-fire antenna array 110. That is, signal routing layer 104-4 acts as a common substrate for both RFIC 2210 and end-fire antenna array 110. The signal routing layer 104-4 may provide signal routing between the RFIC 2210 and end-fire antenna array 110. The one or more conductive layers may—in addition to the signal routing layer 104-4—comprise a plurality of further conductive layers 104-5, 104-6 (L5, L6) underneath the signal routing layer 104-4 (L4). The plurality of further conductive layers 104-5, 104-6 (L5, L6) may comprise a first beamforming network 120-1 for the first polarization and coupled to the plurality of antenna elements 112 via the first routing traces and a second beamforming network 120-2 for the second polarization and coupled to the plurality of antenna elements 112 via the second routing traces. The conductive signal routing layer 104-4 (L4) may be configured to electrically couple the RFIC 2210 to the first and second beamforming networks 120-1, 120-2 and to couple the first and second beamforming networks 120-1, 120-2 to the respective antenna elements 112 of end-fire antenna array 110. As can be seen from FIG. 22, a substrate 2230, such as a motherboard, carries the package 100 including the end-fire antenna array 110 and the RFIC 2210.

As can be seen from FIG. 22, the package 100 may be arranged inside a housing 2240 of the portable device 2200 at an edge of the housing 2240. The housing 2240 may comprise a radome 2250 at least partially covering a top side and a front side of an array aperture of the end-fire antenna array 110. The radome 2250 may act as a structural, weatherproof enclosure that protects antenna array 110. The radome 2250 is constructed of material transparent to radio waves. Radome 2250 may be arranged directly adjacent to the antenna elements 112 of the end-fire antenna array 110 without a keep-out zone between end-fire antenna array 110 and radome 2250. Thus, some examples propose a wideband, dual-polarized beam-switching end-fire AiP (antenna-in-package) architecture integrated with radome 2250 offering no keep-out zone for emerging mmW Wi-Fi 8 R2+ standard (60 GHz).

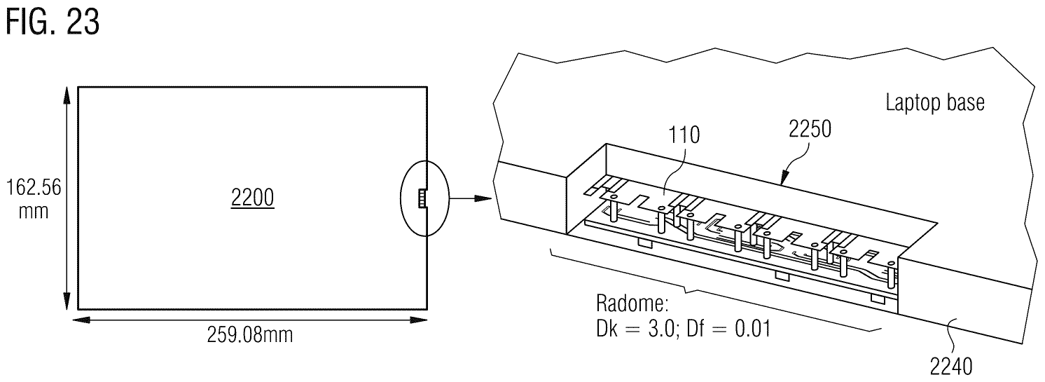

FIG. 23 shows a top view of the portable computing device 2200 with the package 100 being arranged inside the and directly at the right edge of the housing 2240. Radome 2250 may be used as encapsulation and protection for the antenna, and may be made from materials with low loss and low dielectric constant to allow transmission of electromagnetic signals with minimum radiation pattern distortion. The proposed radome structure can be directly attached to the top layer L1 of the array 110 and in front of the array aperture. It can cover the whole or partial of the antenna top and front side depending on the applications. It does not introduce significant frequency detuning issues which often happens in patch-based broadside arrays. The SIW-slot end-fire antenna array configuration with integrated radome may enable wideband operation (57-71 GHz) with tilted beams and enhanced F/B ratio (>26 dB).

End-fire array architectures may experience poor F/B ratio and low gain especially in vertical polarization due to the relatively thin SIW structure. By adding radome 2250 without keep-out zone in the case of implementing the AiM 100 in laptop base, the F/B ratio and gain performance can be effectively improved. The radome 2250 without keep-out zone can function as a near-field dielectric lens and the metallic laptop base can be considered as a reflector on the back of the array 110. They work together to reduce the backside lobe and focus radiation to the front side, thus increasing the gain with F/B improvement.

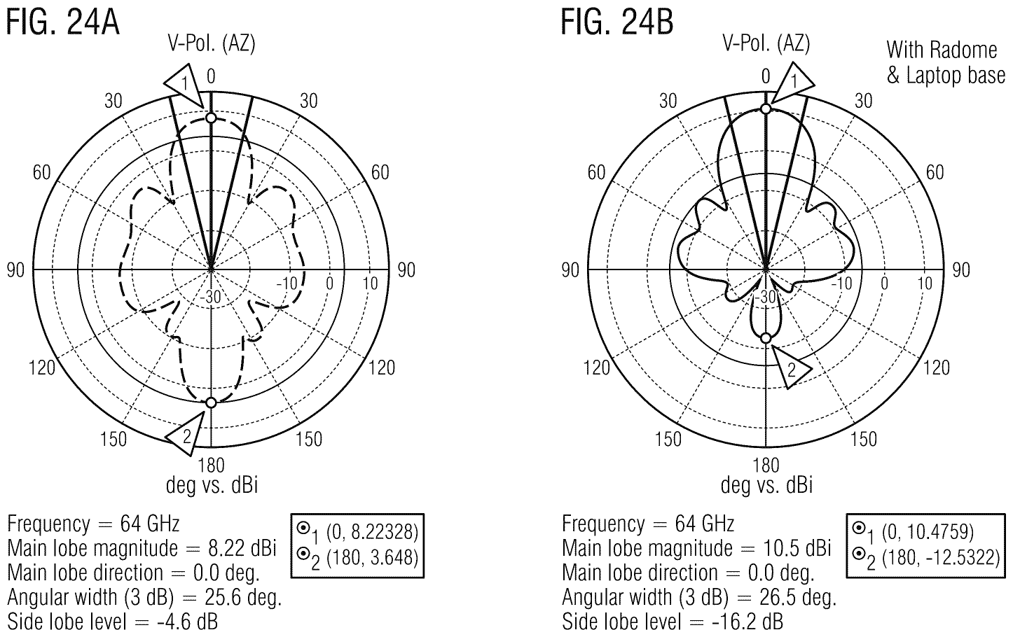

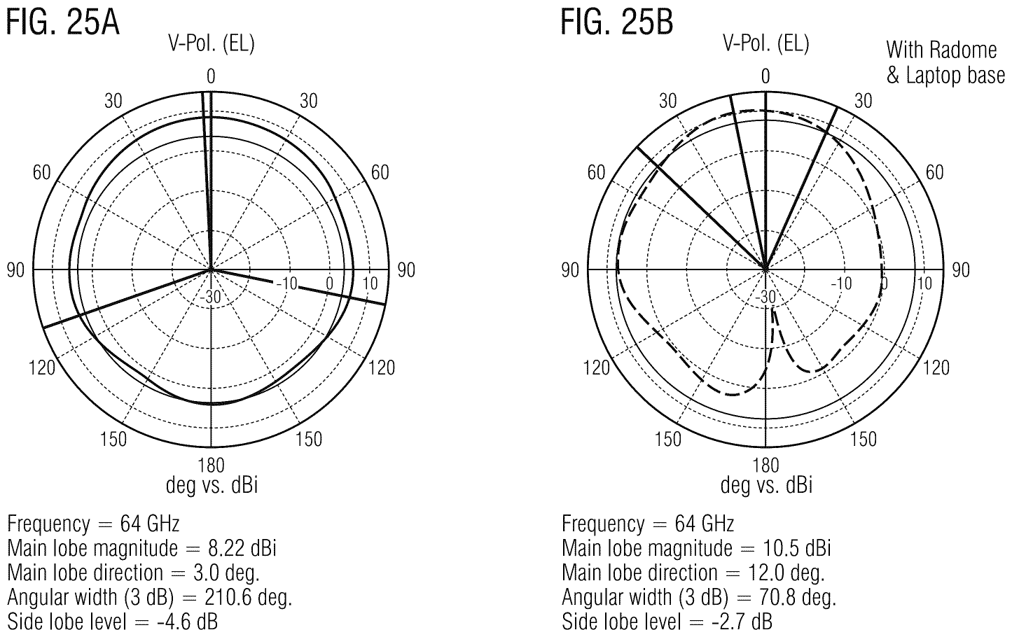

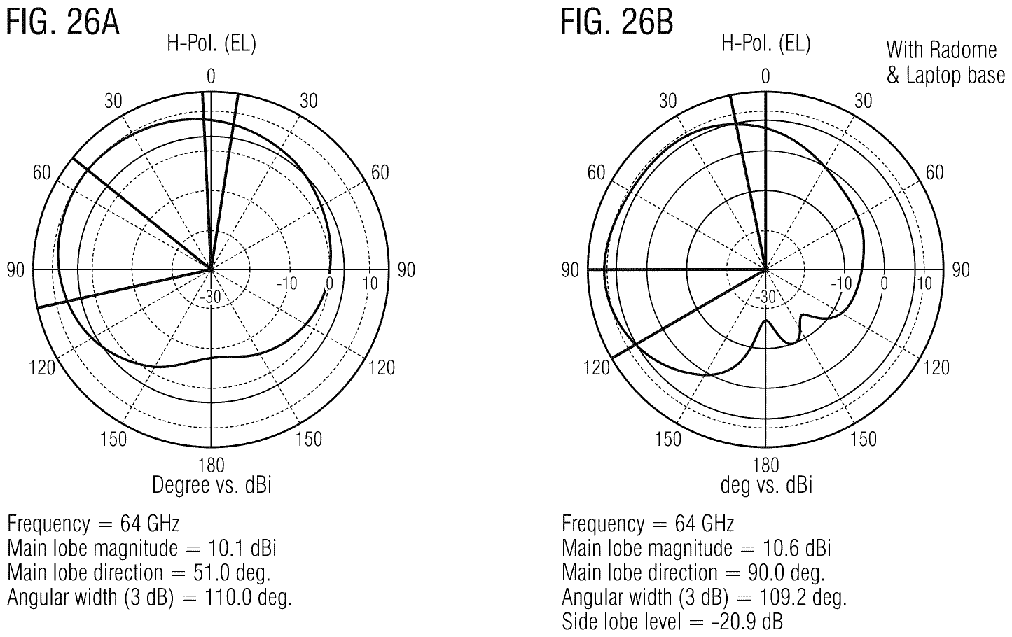

Additionally, when the radome 2250 covers top and front side of the array 110, the main beam can be directed upwards in the elevation plane, which introduces beam tilting feature in vertical polarization, and may enhance the tilting angle in horizontal polarization. Comparison simulation results are shown in FIGS. 24 to 26.

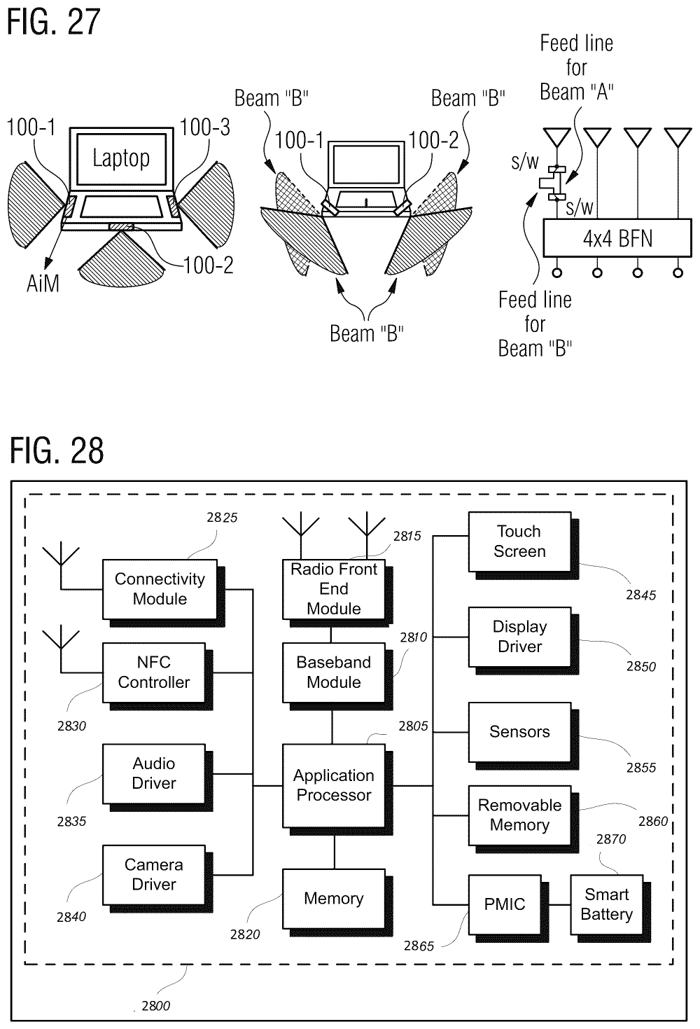

FIG. 27 shows an example configuration of a laptop with a plurality of AiPs 100 arranged at various positions in a laptop base. For example, a first AiP 100-1 may be arranged at a left edge of laptop base, a second AiP 100-2 may be arranged at a front edge of laptop base, and a third AiP 100-3 may be arranged at a right edge of laptop base. Additionally or alternatively, a first AiP 100-1 may be arranged at a left corner of laptop base and a second AiP 100-2 may be arranged at a right corner of laptop base. The AiPs 100 may be configured for beam tilting in the azimuth plane, for example, by selectively changing the electrical lengths of one or more feedlines.

FIG. 28 illustrates a user device 2800 (such as a smartphone, tablet, laptop, etc.) in accordance with an aspect. The user device 2800 may be a mobile device in some aspects and includes an application processor 2805, baseband processor 2810 (also referred to as a baseband module), radio front end module (RFEM) 2815, memory 2820, connectivity module 2825, near field communication (NFC) controller 2830, audio driver 2835, camera driver 2840, touch screen 2845, display driver 2850, sensors 2855, removable memory 2860, power management integrated circuit (PMIC) 2865 and smart battery 2870.

In some aspects, application processor 2805 may include, for example, one or more CPU cores and one or more of cache memory, low drop-out voltage regulators (LDOs), interrupt controllers, serial interfaces such as serial peripheral interface (SPI), inter-integrated circuit (I²C) or universal programmable serial interface module, real time clock (RTC), timer-counters including interval and watchdog timers, general purpose input-output (IO), memory card controllers such as secure digital/multi-media card (SD/MMC) or similar, universal serial bus (USB) interfaces, mobile industry processor interface (MIPI) interfaces and Joint Test Access Group (JTAG) test access ports.

In some aspects, baseband module 2810 may be implemented, for example, as a solder-down substrate including one or more integrated circuits, a single packaged integrated circuit soldered to a main circuit board, and/or a multi-chip module containing two or more integrated circuits.

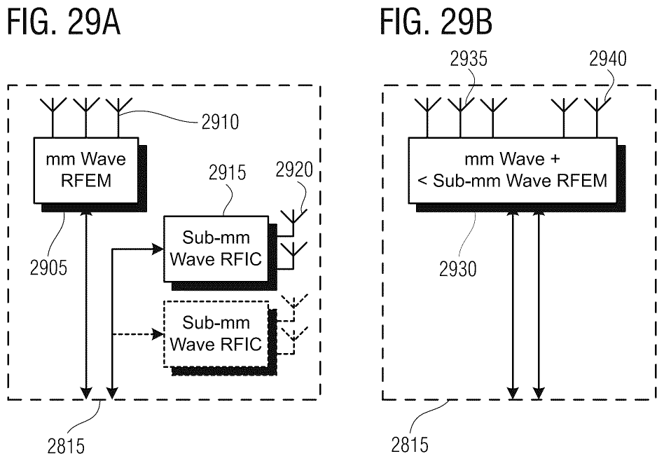

FIG. 29A illustrates an aspect of a radio front end module 2815 incorporating a millimeter wave radio front end module (RFEM) 2905 and one or more sub-millimeter wave radio frequency integrated circuits (RFIC) 2915. In this aspect, the one or more sub-millimeter wave RFICs 2915 may be physically separated from a millimeter wave RFEM 2905. RFICs 2915 may include connection to one or more antennas 2920. RFEM 2905 may be connected to multiple antennas 2910 which may be implemented by AiPs in accordance with the present disclosure.

FIG. 29B illustrates an alternate aspect of a radio front end module 2815. In this aspect both millimeter wave and sub-millimeter wave radio functions may be implemented in the same physical radio front end module 2930. RFEM 2930 may incorporate both millimeter wave antennas 2935 and sub-millimeter wave antennas 2940. Millimeter wave antennas 2935 and sub-millimeter wave antennas 2940 may be implemented by AiPs in accordance with the present disclosure.

The proposed 1-by-4 dual-polarized end-fire AiP can achieve 57-71 GHz wideband operation with high F/B ratio and beam tilting feature for both V- and H-polarizations in elevation plane by exploiting SIW and slot antenna array configuration. By adjusting the length of one of array feed lines, beam tilt in azimuth plane can also be achieved and easily reconfigured electrically for both V- and H-polarizations. The total size of the AiP including compact patch-coupler-based dual BFN (beamforming network) may be 3.8 (D)×10.89 (W)×1.09 (H) mm³ with 6-layer stack-up. The end-fire AiP architecture without the BFN can be also used in phased array approach.

The proposed dual-polarized beam-switching end-fire AiP (antenna-in-package) architecture may enable (1) cost-effective solution for emerging mmW Wi-Fi 8 R2+, (2) enhanced UX with higher data throughputs by tilting the beam in elevation towards Wi-Fi access point, and (3) reduced number of AiMs (Antenna-in-Modules) with azimuth beam tilt to sense user.

The proposed radome design integrated with AiP in laptop base can improve the peak gain and front-to-back ratio of the end-fire array based AiP. It can also support beam tilting/shifting in elevation for both polarizations for both phased array and beam-switching array (with beamforming network). No keep-out zone is required between the antenna array and the radome as well as between AiP and laptop. Unbalanced array feed (one feed line is longer than the others) may enable beam tiling/shifting feature in azimuth for both polarizations for beam-switching (with BFN) array. The beam tilting can be easily achieved electrically. Balanced array feed (symmetric feed pairs have equal length, e.g., 1st & 4th and 2nd & 3rd feed pairs for 1×4 array) can avoid beam shifting in azimuth plane. The proposed design allows solder-down assembly to motherboard without using expensive cables and connectors for further cost saving, and better thermal coupling/dissipation. The proposed design with cost-effective dual-pol end-fire antenna-in-module (AiM) architecture with directors on the top surface of the array may improve peak gain for both polarizations.

The following examples pertain to various techniques of the present disclosure.

An example (e.g. example 1) is directed to an antenna package comprising a layer stack. The layer stack of the antenna package comprises a first plurality of conductive layers forming a plurality of antenna elements of an end-fire antenna array. Each antenna element is configured for a first polarization and for a second polarization. The layer stack of the antenna package further comprises at least one conductive signal routing layer adjacent to or underneath the first plurality of conductive layers. The conductive signal routing layer comprises first routing traces for the first polarization and second routing traces for the second polarization.

Another example (e.g., example 2) relates to a previously-described example (e.g., example 1), wherein the layer stack further comprises a plurality of further conductive layers adjacent to or underneath the signal routing layer, the plurality of further conductive layers comprising a first beamforming network for the first polarization coupled to the plurality of antenna elements via the first routing traces and a second beamforming network for the second polarization coupled to the plurality of antenna elements via the second routing traces, wherein the conductive signal routing layer is configured to electrically couple the first and second beamforming networks to the respective antenna elements.

Another example (e.g., example 3) relates to a previously described example (e.g. example 2), wherein an upper layer of the conductive layers adjacent to or underneath the signal routing layer forms a ground plane for the signal routing layer and a lower layer of the conductive layers adjacent to or underneath the signal routing layer implements the first and second beamforming networks.

Another example (e.g. example 4) relates to a previously described example (e.g., any one of examples 1 to 3), further comprising a solder-down assembly adjacent to or underneath the layer stack and configured to provide electrical and mechanical connection of the semiconductor package to a printed circuit board (PCB).

Another example (e.g. example 5) relates to a previously described example (e.g., any one of examples 1 to 4), wherein each of the antenna elements comprises a substrate integrated waveguide (SIW) formed in the first plurality of conductive layers for the first polarization and a planar antenna formed in a top layer of first plurality of conductive layers for the second polarization.

Another example (e.g. example 6) relates to a previously described example (e.g., any one of examples 1 to 5), wherein the first plurality of conductive layers forming the end-fire antenna array form a volume in x-, y-, and z-dimension, wherein adjacent antenna elements are aligned in x-direction.

Another example (e.g. example 7) relates to a previously described example (e.g., any one of examples 5 or 6), wherein the first plurality of conductive layers comprises a top layer spanning an x-y-plane, and wherein each antenna element comprises a respective radiation slot in the top layer and having a longitudinal extension in y-direction.

Another example (e.g. example 8) relates to a previously-described example (e.g., example 7), wherein the first plurality of conductive layers comprises a bottom layer spanning an x-y-plane, wherein each antenna element comprises a first and a second vertical via having a longitudinal extension in z-direction and connecting the bottom layer and the top layer, wherein first and the second vertical vias are arranged symmetrically on opposite sides of the respective radiation slot.

Another example (e.g. example 9) relates to a previously described example (e.g., example 8), wherein the respective SIW of each antenna element comprises a respective plurality of vertical conductive posts having longitudinal extensions in z-direction and connecting the bottom layer and the top layer of the first plurality of conductive layers.

Another example (e.g. example 10) relates to a previously described example (e.g., any one of examples 7 or 9), wherein the top layer comprises a decoupling slot between adjacent antenna elements of the plurality of antenna elements, the decoupling slot having a longitudinal extension in y-direction.

Another example (e.g. example 11) relates to a previously described example (e.g., example 10), wherein the longitudinal extension of the decoupling slot is larger than the longitudinal extension of the radiation slot.

Another example (e.g. example 12) relates to a previously described example (e.g., any one of examples 8 to 11), wherein the bottom layer of the first plurality of conductive layers forms a ground plane for the end-fire antenna array.

Another example (e.g. example 13) relates to a previously described example (e.g., any one of examples 7 to 12), wherein the first plurality of conductive layers comprises a middle layer between the bottom layer and the top layer, the middle layer comprising respective feedlines for exciting the respective radiation slot and respective probes for exciting the respective SIW.

Another example (e.g. example 14) relates to a previously described example (e.g., example 13), wherein a feedline has an end portion extending x-direction.

Another example (e.g. example 15) relates to a previously described example (e.g., any one of examples 1 to 14), wherein the conductive signal routing layer is a single layer spanning an x-y-plane and comprising feedlines of different lengths for different antenna elements.

Another example (e.g. example 16) relates to a previously described example (e.g., example 15), wherein a feedline for a first SIW of a first antenna element has a different length than a feedline for a second SIW polarization of a second antenna element, and/or a feedline for a first radiation slot of the first antenna element has a different length than a feedline for a second radiation slot of the second antenna element.

Another example (e.g. example 17) relates to a previously described example (e.g., any one of examples 7 to 16), wherein the top layer comprises a plurality of parasitic directors associated with the plurality of antenna elements.

Another example (e.g. example 18) relates to a previously described example (e.g., any one of examples 1 to 17), wherein the adjacent conductive layers of the layer stack are separated by a package substrate layer.

Another example (e.g. example 19) relates to a previously described example (e.g., any one of examples 1 to 18), further comprising at least a portion of a radio frequency integrated circuit (RFIC) laterally adjacent to the plurality of antenna elements of the end-fire antenna array.

Another example (e.g. example 20) relates to a previously described example (e.g., example 19), wherein the least one conductive signal routing layer forms a substrate for the RFIC or the portion thereof.

Another example (e.g. example 21) is directed to device comprising an antenna package comprising the end-fire antenna array of any one of the previous examples, and an RFIC arranged laterally adjacent to the end-fire antenna array on a side opposite to a radiation or reception direction of the end-fire antenna array, and a substrate carrying the semiconductor package and the RFIC.

Another example (e.g. example 22) relates to a previously described example (e.g., example 21), wherein the device is a portable computing device and the semiconductor package is arranged at an edge of a housing of the portable computing device.

Another example (e.g. example 23) relates to a previously described example (e.g., example 21 or 22), wherein the substrate comprises a motherboard of the portable computing device.

Another example (e.g. example 24) relates to a previously described example (e.g., any one of examples 21 to 23), further comprising a radome at least partially covering a top side and a front side of an array aperture of the end-fire antenna array.

Another example (e.g. example 25) relates to a previously described example (e.g., example 24), wherein the radome is arranged directly adjacent to the antenna elements of the end-fire antenna array without a keep-out zone.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A semiconductor package, comprising
a layer stack comprising
a first plurality of conductive layers forming a plurality of antenna elements of an end-fire antenna array, wherein each antenna element is configured for a first polarization and for a second polarization; and
at least one conductive signal routing layer adjacent to the first plurality of conductive layers, the conductive signal routing layer comprising first routing traces for the first polarization and second routing traces for the second polarization.

2. The semiconductor package of claim 1, wherein the layer stack further comprises
a plurality of further conductive layers adjacent to the signal routing layer, the plurality of further conductive layers comprising a first beamforming network for the first polarization coupled to the plurality of antenna elements via the first routing traces and a second beamforming network for the second polarization coupled to the plurality of antenna elements via the second routing traces, wherein
the conductive signal routing layer is configured to electrically couple the first and second beamforming networks to the respective antenna elements.

3. The semiconductor package of claim 2, wherein an upper layer of the conductive layers adjacent to the signal routing layer forms a ground plane for the signal routing layer and a lower layer of the conductive layers adjacent to the signal routing layer implements the first and second beamforming networks.

4. The semiconductor package of claim 1, further comprising
a solder-down assembly coupled to the layer stack and configured to provide electrical and mechanical connection of the semiconductor package to a printed circuit board, PCB.

5. The semiconductor package of claim 1, wherein each of the antenna elements comprises a substrate integrated waveguide, SIW, formed in the first plurality of conductive layers for the first polarization and a planar antenna formed in a top layer of first plurality of conductive layers for the second polarization.

6. The semiconductor package of claim 1, wherein the first plurality of conductive layers forming the end-fire antenna array span a volume in x-, y-, and z-dimension, wherein adjacent antenna elements are aligned in x-direction.

7. The semiconductor package of claim 5, wherein the first plurality of conductive layers comprises a top layer spanning an x-y-plane, and wherein each antenna element comprises a respective radiation slot in the top layer and having a longitudinal extension in y-direction.

8. The semiconductor package of claim 7, wherein the first plurality of conductive layers comprises a bottom layer spanning an x-y-plane, wherein each antenna element comprises a first and a second vertical via having a longitudinal extension in z-direction and connecting the bottom layer and the top layer, wherein first and the second vertical vias are arranged symmetrically on opposite sides of the respective radiation slot.

9. The semiconductor package of claim 8, wherein the respective SIW of each antenna element comprises a respective plurality of vertical conductive posts having longitudinal extensions in z-direction and connecting the bottom layer and the top layer of the first plurality of conductive layers.

10. The semiconductor package of claim 7, wherein the top layer comprises a decoupling slot between adjacent antenna elements of the plurality of antenna elements, the decoupling slot having a longitudinal extension in y-direction.

11. The semiconductor package of claim 10, wherein the longitudinal extension of the decoupling slot is larger than the longitudinal extension of the radiation slot.

12. The semiconductor package of claim 8, wherein the bottom layer of the first plurality of conductive layers forms a ground plane for the end-fire antenna array.

13. The semiconductor package of claim 7, wherein the first plurality of conductive layers comprises a middle layer between the bottom layer and the top layer, the middle layer comprising respective feedlines for exciting the respective radiation slot and respective probes for exciting the respective SIW.

14. The semiconductor package of claim 13, wherein a feedline has an end portion extending x-direction.

15. The semiconductor package of claim 1, wherein the conductive signal routing layer is a single layer spanning an x-y-plane and comprising feedlines of different lengths for different antenna elements.

16. The semiconductor package of claim 15, wherein
a feedline for a first SIW of a first antenna element has a different length than a feedline for a second SIW polarization of a second antenna element, and/or
a feedline for a first radiation slot of the first antenna element has a different length than a feedline for a second radiation slot of the second antenna element.

17. The semiconductor package of claim 7, wherein the top layer comprises a plurality of parasitic directors associated with the plurality of antenna elements.

18. The semiconductor package of claim 1, wherein the adjacent conductive layers of the layer stack are separated by a substrate layer.

19. The semiconductor package of claim 1, further comprising at least a portion of a radio frequency integrated circuit, RFIC, laterally adjacent to the plurality of antenna elements of the end-fire antenna array.

20. The semiconductor package of claim 19, wherein the least one conductive signal routing layer forms a substrate for the RFIC or the portion thereof.

21. A device, comprising
a semiconductor package comprising a layer stack, the layer stack comprising
a first plurality of conductive layers forming a plurality of antenna elements of an end-fire antenna array, wherein each antenna element is configured for a first polarization and for a second polarization; and
at least one conductive signal routing layer adjacent to the first plurality of conductive layers, the conductive signal routing layer comprising first routing traces for the first polarization and second routing traces for the second polarization;
an RFIC arranged laterally adjacent to the end-fire antenna array on a side opposite to a radiation or reception direction of the end-fire antenna array; and
a substrate carrying the semiconductor package and the RFIC.

22. The device of claim 21, wherein the device is a portable computing device and the semiconductor package is arranged at an edge of a housing of the portable computing device.

23. The device of claim 21, wherein the substrate comprises a motherboard of the portable computing device.

24. The device of claim 21, further comprising
a radome at least partially covering a top side and a front side of an array aperture of the end-fire antenna array.

25. The device of claim 24, wherein the radome is arranged directly adjacent to the antenna elements of the end-fire antenna array without a keep-out zone.
